(19) United States
(12) Patent Application Publication
(10) Pub. No.: US 2026/0127344 A1
(43) Pub. Date: May 7, 2026

(54) GENERATING A HARDWARE DESCRIPTION FOR CONFIGURING A DIGITAL ELECTRONIC CIRCUIT TO PARSE DATA ACCORDING TO A GRAMMAR

(71) Applicant: Garrison Technology Ltd., London (GB)

(72) Inventors: Edward FROSZTEGA, London (GB); Stefan STOECKIGT, London (GB)

(73) Assignee: Garrison Technology Ltd., London (GB)

(21) Appl. No.: 19/033,744

(22) Filed: Jan. 22, 2025

(30) Foreign Application Priority Data
Nov. 5, 2024 (GB) 2416310.7

(51) Int. Cl. G06F 30/33; G06F 30/327; G06F 40/211; G06F 40/284

(52) U.S. Cl. CPC G06F 30/33; G06F 30/327; G06F 40/211; G06F 40/284

(57) ABSTRACT

Generating a hardware description for configuring a digital electronic circuit, such as an application-specific integrated circuit (ASIC) or a field-programmable gate array (FPGA), wherein the hardware description configures the digital electronic circuit to parse input data comprising a sequence of input tokens against a grammar such as an LL(1) grammar. This is achieved by implementing circuitry for a transition network representing the grammar within the digital electronic circuit. Implementations include circuitry for performing actions and checking conditions in accordance with action and condition elements of a grammar description. When the grammar defines a data format, such as a JSON schema, XML Schema Definition (XSD), or ASN.1 schema, a document can be validated against the data format by the configured digital electronic circuit processing the document as the input data.

### CROSS-REFERENCE TO RELATED APPLICATIONS

This application claims the benefit of and priority under 35 U.S.C. § 119 (e) to United Kingdom Patent Application No. 2416310.7, filed Nov. 5, 2024, and titled “Generating A Hardware Description For Configuring A Digital Electronic Circuit To Parse Data According To A Grammar”, which is incorporated herein by reference in its entirety.

### TECHNICAL FIELD

This disclosure relates to generating a hardware description for configuring a digital electronic circuit to parse input data comprising a sequence of input tokens against a grammar that defines a data format. This disclosure also relates to a method of configuring a digital electronic circuit to parse input data, and a digital electronic circuit configured accordingly.

### BACKGROUND

Security concerns arise in applications where datasets obtained from untrusted sources are processed. For example, when data is processed, malicious code or the like could be hidden within the data, which could lead to a security breach in the computer system processing the data. One particular concern is that the data may include malicious code that could cause the processing device to execute arbitrary code.

One way to mitigate such risks is to validate data before subsequent processing, wherein the data is validated against a particular expected data format, for example a schema, such as a JSON Schema, XML Schema Definition (XSD), or ASN.1 schema. This confirms that the data conforms to the schema, and thus reduces the risk of any malicious code being included within the data, because it is unlikely that such malicious code would conform to the schema.

One way to validate data to a data format is by parsing. For example, data may be parsed using parsing software run on a general-purpose computer. The parsing software processes all of the data and compares it to what is permitted according to the data format. If the parsing software is able to fully parse the data, then the data is confirmed to accord with the data format. If the parsing software fails to parse the data fully, then the data does not accord with the data format. The ANTLR software tool (Another Tool for Language Recognition; see https://www.antlr.org/) may be used in the software-parsing process. The ANTLR software tool takes, as input, a grammar that specifies a language and outputs source code for a recogniser of that language. It can therefore be used with a grammar specifying a data format to generate source code for a recogniser of that data format.

### SUMMARY

Techniques in accordance with this disclosure include generating a hardware description for configuring a digital electronic circuit, such as an application-specific integrated circuit (ASIC) or a field-programmable gate array (FPGA), wherein the hardware description configures the digital electronic circuit to parse input data comprising a sequence of input tokens against a grammar such as an LL(1) grammar. This is achieved by implementing a transition network representing the grammar within the digital electronic circuit. Implementations include circuitry for performing actions and checking conditions in accordance with condition elements or in accordance with action and condition elements of a grammar description. When the grammar defines a data format, such as a JSON schema, XML Schema Definition (XSD), or ASN.1 schema, a document can be validated against the data format by the configured digital electronic circuit processing the document as the input data. Some grammar descriptions might include condition elements without associated action elements.

According to a first aspect there is provided a computer-implemented method of generating a hardware description for configuring a digital electronic circuit to parse input data comprising a sequence of input tokens against a grammar that defines a data format, wherein the grammar is codified in a grammar description that includes one or more condition elements, or includes one or more action elements and one or more condition elements. The grammar is codified in a grammar description that includes one or more condition elements that comprise computer code that define functions that provide Boolean output based on values stored in memory. A graph represents a transition network based on the rules of the grammar and includes one or more condition edges, each associated with a condition element. The hardware description is generated based on the transition network and is in the form of one or both of a netlist and a hardware description language such as HDL or Verilog. The grammar description includes implemented circuitry for a condition edge, the implemented circuitry configured to evaluate the function defined in the computer code of the associated condition element based on a stored value in memory. Based on the output of the function, the implemented circuitry may selectively permit propagation of a logical high through the implemented circuitry at a location downstream of the storing of the value in the memory.

According to a further aspect, there is provided a computer-implemented method of generating a hardware description for configuring a digital electronic circuit to parse input data comprising a sequence of input tokens against a grammar that defines a data format, wherein the grammar is codified in a grammar description that includes one or more condition elements, or includes one or more action elements and one or more condition elements. A condition element comprises computer code that defines a function that provides a Boolean output based on at least one value stored in memory. An action element comprises computer code for an operation that comprises storing a value in memory. A digitally stored graph represents a transition network (such as an Augmented Transition Network) based on the rules of the grammar. The transition network may comprise one or more action edges, each associated with an action element of the grammar description. The transition network may comprise one or more condition edges, each associated with a condition element of the grammar description. Some grammar descriptions may comprise one or more condition elements without any action elements. A hardware description is generated based on the transition network. The hardware description may be in a hardware description language such as HDL or Verilog. The hardware description may be in the form of a netlist. Generating the hardware description includes implementing a memory in the hardware description, the memory configured to store a value and provide the stored value as output from the memory. The grammar description includes implemented circuitry for a condition edge of the one or more condition edges. The implemented circuitry for the condition edge is configured to evaluate the function defined in the computer code of the associated condition element based on a stored value in memory. Based on the output of the function, the implemented circuitry may selectively permit propagation of a logical high through the implemented circuitry at a location downstream of the storing of the value in the memory. In some examples, the condition edge is configured to evaluate the function defined in the computer code of the associated condition element based on a stored value derived from one or more input tokens of the input data. In some examples the hardware description includes implemented circuitry for an action edge including circuitry configured to perform an operation in accordance with the computer code of the associated action element, wherein the operation stores a first value in the memory. Implemented circuitry for a condition edge of the one or more condition edges including circuitry configured to evaluate the function defined in the computer code of the associated condition element based on the first value, and, based on the output of the function, selectively permit propagation of a logical high through implemented circuitry at a location downstream of storing of the first value in the memory. In some examples where the grammar description includes a condition element without an associated action element, the hardware description includes implemented circuitry for a condition edge of the one or more condition edges including circuitry configured to, store a first value derived from one or more input tokens in the memory and, at a location within the digital electronic circuit downstream of the storing of the first value in the memory, evaluate the function defined in the computer code of the associated condition element based on a comparison between the stored value derived from one or more input tokens in the memory and the comparison value, and, based on the output of the function, selectively permit propagation of a logical high through implemented circuitry at a location downstream of the storing of the first value in the memory.

According to a further aspect, there is provided a computer-implemented method of generating a hardware description for configuring a digital electronic circuit to parse input data comprising a sequence of input tokens against a grammar that defines a data format, wherein the grammar is codified in a grammar description that includes one or more condition elements, wherein a condition element comprises computer code that defines a function that provides a Boolean output based on at least one value stored in memory, wherein the method comprises: providing a digitally stored graph representing a transition network based on the rules of the grammar, wherein: a) the transition network comprises a plurality of vertices and a plurality of directed edges connected between vertices, each directed edge connected between a respective source vertex and destination vertex, the plurality of directed edges of the transition network comprising a plurality of input-consuming edges and a plurality of non-input-consuming edges, the plurality of non-input-consuming edges including one or more action edges and one or more condition edges, b) each input-consuming edge represents a transition between its source vertex and its destination vertex conditional on a current input token of the input data matching an input-consumption condition associated with the input-consuming edge, wherein parsing of the input data advances to a next input token of the input data with the transition, c) each non-input-consuming edge represents a transition between its source vertex and its destination vertex without the parsing of the input data advancing to a next input token of the input data with the transition, and d) each condition edge of the one or more condition edges is associated with a condition element of the grammar description, wherein at least one condition edge of the one or more condition edges is associated with a condition element that comprises computer code that defines a function that provides a Boolean output based on a comparison between a stored value derived from one or more input tokens and a comparison value. The method further comprises generating the hardware description in a hardware description language or as a netlist based on the transition network by: a) implementing an input buffer in the hardware description to store a sequence of input tokens of the input data, the input buffer configured to provide an input token of the sequence of input tokens as output from the input buffer, wherein the input buffer is further configured to sequentially advance through the sequence of input tokens by, on a clock tick, providing a next input token as output from the input buffer, b) implementing a memory in the hardware description, the memory configured to store a value and provide the stored value as output from the memory, c) implementing circuitry in the hardware description for the edges and vertices of the transition network. The implemented circuitry for each vertex is electrically connected to the implemented circuitry for each edge that is connected to the vertex in the transition network, the implemented circuitry for each vertex configured to output a logical high to circuitry for all outgoing directed edges of that vertex if circuitry for an incoming directed edge of that vertex provides a logical high. The implemented circuitry for each input-consuming edge comprises a register with associated logic configured to compare an input token provided as output from the input buffer with the input-consumption condition associated with that input-consuming edge, the register with associated logic configured to, if the implemented circuitry for the source vertex of the input-consuming edge provides a logical high and the input token provided as output from the input buffer satisfies the input-consumption condition of the input-consuming edge, provide a logical high to circuitry for the destination vertex of the input-consuming edge on a next clock tick, the input buffer advancing to a next input token and providing the next input token as output from the input buffer on said next clock tick. The implemented circuitry for each non-input-consuming edge comprises a coupling between circuitry for the source vertex of the non-input-consuming edge and circuitry for the destination vertex of the non-input-consuming edge. The implemented circuitry for the at least one condition edge of the one or more condition edges is configured to store a first value derived from one or more input tokens in the memory and, at a location within the digital electronic circuit downstream of the storing of the first value in the memory, evaluate the function defined in the computer code of the associated condition element based on a comparison between the stored value derived from one or more input tokens in the memory and the comparison value, and, based on the output of the function, selectively permit propagation of a logical high through implemented circuitry at a location downstream of the storing of the first value in the memory.

According to a further aspect, there is provided a computer-implemented method of generating a hardware description for configuring a digital electronic circuit to parse input data comprising a sequence of input tokens against a grammar that defines a data format, wherein the grammar is codified in a grammar description that includes one or more action elements and one or more condition elements, wherein an action element comprises computer code for an operation that comprises storing a value in memory, wherein a condition element comprises computer code that defines a function that provides a Boolean output based on at least one value stored in memory, wherein the method comprises providing a digitally stored graph representing a transition network based on the rules of the grammar. The transition network comprises a plurality of vertices and a plurality of directed edges connected between vertices, each directed edge connected between a respective source vertex and destination vertex, the plurality of directed edges of the transition network comprising a plurality of input-consuming edges and a plurality of non-input-consuming edges, the plurality of non-input-consuming edges including one or more action edges and one or more condition edges. Each input-consuming edge represents a transition between its source vertex and its destination vertex conditional on a current input token of the input data matching an input-consumption condition associated with the input-consuming edge, wherein parsing of the input data advances to a next input token of the input data with the transition. Each non-input-consuming edge represents a transition between its source vertex and its destination vertex without the parsing of the input data advancing to a next input token of the input data with the transition. Each action edge of the one or more action edges is associated with an action element of the grammar description. Each condition edge of the one or more condition edges is associated with a condition element of the grammar description. The method further comprises generating the hardware description in a hardware description language or as a netlist based on the transition network by: a) implementing an input buffer in the hardware description to store a sequence of input tokens of the input data, the input buffer configured to provide an input token of the sequence of input tokens as output from the input buffer, wherein the input buffer is further configured to sequentially advance through the sequence of input tokens by, on a clock tick, providing a next input token as output from the input buffer, b) implementing a memory in the hardware description, the memory configured to store a value and provide the stored value as output from the memory, and c) implementing circuitry in the hardware description for the edges and vertices of the transition network. The implemented circuitry for each vertex is electrically connected to the implemented circuitry for each edge that is connected to the vertex in the transition network, the implemented circuitry for each vertex configured to output a logical high to circuitry for all outgoing directed edges of that vertex if circuitry for an incoming directed edge of that vertex provides a logical high. The implemented circuitry for each input-consuming edge comprises a register with associated logic configured to compare an input token provided as output from the input buffer with the input-consumption condition associated with that input-consuming edge, the register with associated logic configured to, if the implemented circuitry for the source vertex of the input-consuming edge provides a logical high and the input token provided as output from the input buffer satisfies the input-consumption condition of the input-consuming edge, provide a logical high to circuitry for the destination vertex of the input-consuming edge on a next clock tick, the input buffer advancing to a next input token and providing the next input token as output from the input buffer on said next clock tick. The implemented circuitry for each non-input-consuming edge comprises a coupling between circuitry for the source vertex of the non-input-consuming edge and circuitry for the destination vertex of the non-input-consuming edge. The implemented circuitry for an action edge of the one or more action edges comprises circuitry configured to perform an operation in accordance with the computer code of the associated action element, wherein the operation stores a first value in the memory. The implemented circuitry for a condition edge of the one or more condition edges is configured to, at a location within the digital electronic circuit downstream of the implemented circuitry for the action edge that stores the first value in the memory, evaluate the function defined in the computer code of the associated condition element based on the first value, and, based on the output of the function, selectively permit propagation of a logical high through implemented circuitry at a location downstream of the implemented circuitry for the action edge that stores the first value in the memory.

According to a further aspect there is provided a method of configuring a digital electronic circuit to parse input data, the method comprising: generating a hardware description in accordance with any of the above-described methods; and configuring a digital electronic circuit based on the hardware description. Optionally the digital electronic circuit may be an application-specific integrated circuit, ASIC, or a field-programmable gate array, FPGA.

According to a further aspect there is provided a digital electronic circuit produced according to the above-described methods.

According to a further aspect there is provided a computer system comprising a memory having stored thereon instructions and a processor, the processor configured to execute the instructions stored in the memory to perform any of the above-described methods.

The techniques of this disclosure address a problem with existing approaches to parsing data against a grammar that defines a data format in order to validate that data before subsequent processing, with the aim of reducing the risk of malicious code causing arbitrary code execution on the devices performing the subsequent processing. Specifically, an existing approach may generate source code for software to parse data, wherein the software is run on a general-purpose computer, i.e. a Turing-complete machine. This means that the parsing software run on a general-purpose computer is itself susceptible to malicious code in the data, and may potentially be caused to execute arbitrary code including code to cause the parsing to software to falsely parse data that includes malicious code, allowing such data to be subsequently processed by downstream computers. This represents a potential security risk.

The techniques of this disclosure provide a hardware description for configuring a digital electronic circuit to parse input data comprising a sequence of input tokens against a grammar that defines a data format. Unlike a general-purpose computer, the digital electronic circuit may be a non-Turing-complete machine. The digital electronic circuit may be an application-specific integrated circuit (ASIC), where the functionality of the circuit is fixed at manufacture. The digital electronic circuit may be a field-programmable gate array, where the functionality of the circuit may be configurable but not by data processed by the FPGA. Typically, the FPGA is configurable via an entirely separate channel to any input/output channel of the FPGA that is used to input or output data to be processed. The use of a digital electronic circuit to perform parsing of input data is therefore potentially more secure than use of parsing software on a general-purpose computer. However, a disadvantage to the use of a digital electronic circuit in such a way in that it might be relatively inflexible. It may be difficult to modify the digital electronic circuit to parse data according to a new data format, such as an arbitrary or custom data format. By contrast, for parsing software run on a general-purpose computer, a tool such as ANTLR can be used to generate new parsing software for any arbitrary data format. This software can be run on the same general-purpose computer. Essentially, the design process for hardware such as a digital electronic circuit is more intensive or laborious than the design process for a software parser, particularly using a tool such as ANTLR.

### BRIEF DESCRIPTION OF DRAWINGS

Embodiments will now be described in relation to the accompanying drawings, in which:

FIG. 1 shows a standard RTN representation for an example grammar;

FIG. 2 shows a modified version of the RTN representation of FIG. 1;

FIG. 3 shows a schematic logical diagram of a digital electronic circuit created according to a hardware description generated based on the RTN of FIG. 2;

FIG. 4 shows a version of the RTN representation of FIG. 2 modified by inlining;

FIG. 5 shows a schematic logical diagram of a digital electronic circuit created according to a hardware description generated based on the RTN of FIG. 4;

FIG. 6 shows a schematic logical diagram of a digital electronic circuit created according to a hardware description generated based on the RTN of FIG. 4;

FIG. 7 shows an RTN representation for an example grammar;

FIGS. 8A and 8B, collectively referred to herein as FIG. 8, show an ATN representation for an example grammar description including action and condition elements;

FIG. 9 shows an ATN representation for an example grammar description including action and condition elements;

FIG. 10 shows a schematic logical diagram of a portion of a digital electronic circuit created according to a hardware description generated based on the ATN of FIG. 9;

FIG. 11 shows a schematic logical diagram of a portion of a digital electronic circuit created according to a hardware description generated based on the ATN of FIG. 9;

FIG. 12 shows an ATN representation for an example grammar description including action and condition elements;

FIG. 13 shows an ATN representation equivalent to the ATN representation of FIG. 12;

FIG. 14 shows an ATN representation equivalent to the ATN representation of FIG. 12;

FIG. 15 shows an ATN representation equivalent to the ATN representation of FIG. 12;

FIG. 16 shows an ATN representation for an example grammar description including a condition element;

FIG. 17 shows a schematic logical diagram of a digital electronic circuit created according to a hardware description generated based on the ATN of FIG. 16;

FIG. 18 shows an ATN representation for an example grammar description including a condition element;

FIG. 19 shows a schematic logical diagram of a digital electronic circuit created according to a hardware description generated based on the ATN of FIG. 18; and

FIG. 20 shows a schematic logical diagram of an alternative digital electronic circuit created according to a hardware description generated based on the ATN of FIG. 18.

### DETAILED DESCRIPTION

The techniques of this disclosure include a method of generating a hardware description for configuring a digital electronic circuit, such as an application-specific integrated circuit (ASIC) or a field-programmable gate array (FPGA). The hardware description configures the digital electronic circuit to parse input data comprising a sequence of input tokens against a grammar. This is achieved by implementing a transition network such as a recursive transition network (RTN) or an augmented transition network (ATN) representing the grammar within the digital electronic circuit. When the grammar defines a data format, such as a JSON schema, XML Schema Definition (XSD), or ASN.1 schema, a document can be validated against the data format by the configured digital electronic circuit processing the document as the input data. The method may be computer-implemented. The method may therefore be performed by a computer to automatically generate a hardware description and optionally also automatically configure a digital electronic circuit based on the hardware description for an arbitrary data format defined by a grammar. The grammar may be a context-free grammar that additionally includes rules defined by actions and conditions. The grammar may be an LL(1) grammar.

The techniques of this disclosure relate to a grammar codified in a grammar description that includes: i) one or more condition elements, or ii) one or more action elements and one or more condition elements. An RTN is a class of transition network that does not strictly include action elements or condition elements. However, it will be helpful to discuss RTNs and their hardware implementation initially and to later introduce into this discussion the action and condition elements. In addition, the use of embedded networks in an RTN as described herein is applicable in the implementation of a transition network for a grammar description that includes one or more condition elements or includes one or more action elements and one or more condition elements. In other words, techniques presented herein for the generation of a hardware description for configuring a digital electronic circuit to parse input data comprising a sequence of input tokens against a grammar that defines a data format, wherein the grammar is codified in a grammar description that includes one or more condition elements or includes one or more action elements and one or more condition elements, may be implemented by providing a digitally stored graph representing a transition network based on the rules of the grammar wherein the transition network comprises one or more networks including a first embedded network that is embedded within itself and/or at least one other network. In other words, examples presented herein in respect of RTNs or transition networks representative of grammars that do not include actions and conditions, including the use in such examples of embedded networks and the implementation of embedded networks in a hardware description, are compatible with grammars that include actions and conditions.

Hardware Implementation of RTN with Embedded Networks

A simple grammar is described in TABLE 1:

TABLE 1

content: START value EOF ;
value: DIGIT+ | array ;
array: OPEN_BRACKET value (COMMA value)*
CLOSE_BRACKET ;

This grammar is an LL(1) grammar. It has been expressed above using ANTLR G4 notation. ANTLR G4 notation is used by version 4 of the ANTLR (Another Tool for Language Recognition) software parser generator tool. Derivation of a grammar for a particular data format, such as a particular JSON schema, may be done manually or automatically/programmatically according to established techniques in this technical field. The resulting grammar may be expressed digitally using ANTLR G4 notation or using other digital grammar notations. Each of “content”, “value” and “array” in TABLE 1, i.e. the elements that begin each line of Table 1, are referred to as rules within the grammar.

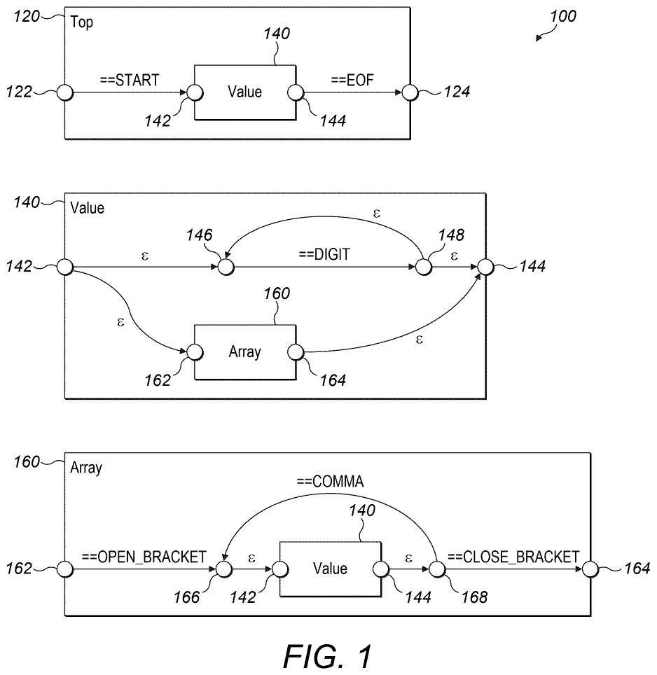

A Recursive Transition Network (RTN) may be generated for an LL(1) grammar according to established techniques in this technical field. FIG. 1 shows an RTN representation 100 for the example grammar of Table 1. The RTN 100 includes three networks: i) a first network 120 (labelled ‘Top’ in FIG. 1, corresponding to the rule “content”), ii) a first embedded network 140 (labelled ‘Value’ in FIG. 1, corresponding to the rule “value”), and iii) a second embedded network 160 (labelled ‘Array’ in FIG. 1, corresponding to the rule “array”). In the RTN 100 of FIG. 1, the first embedded network 140 is embedded within both the first network 120 and the second embedded network 160, and the second embedded network 160 is embedded within the first embedded network 140.

Within the technical field of transition networks and RTNs in particular, a transition to an embedded network from a network in which it is embedded may be referred to as a ‘call’ to the embedded network. Moving back from the embedded network to the network in which it is embedded may be referred to as a ‘return’. A return from an embedded network should return to the network from which the corresponding call to that embedded network was made.

For example, in the RTN 100 of FIG. 1, if a first call is made from the first network 120 to the first embedded network 140, and then a second call is subsequently made from the first embedded network 140 to the second embedded network 160, and then a third call is subsequently made from the second embedded network 160 to the first embedded network 140, a return corresponding to the third call must be made from the first embedded network 140 to the second embedded network 160, and then a return corresponding to the second call must subsequently be made from the second embedded network 160 to the first embedded network 140, and then a return corresponding to the first call must subsequently be made from the first embedded network 140 to the first network 120. In other words, the steps of calling and returning within an RTN should follow a correct sequence for proper operation of the RTN. The techniques of this disclosure concern the generation of a hardware description for a digital electronic circuit that implements a transition network such as an RTN.

In general, the structure of the networks of the transition network (e.g. RTN) is defined by the specific grammar of the transition network. Each embedded network may be embedded within itself (one or more times) and/or at least one other network of the transition network (RTN). The embedding of the networks can lead to a recursive property in the transition network (RTN). There are two types of recursion. Firstly, a network may be recursively embedded within itself, such that it may call itself any number of times. This can be described as direct recursion. Secondly, a first network may be embedded in another network which is itself embedded in the first network. In such a case, the first network is indirectly recursively embedded within itself, resulting in recursion. This can be described as indirect recursion.

Looking at FIG. 1 in more detail, the networks 120,140,160 each include a number of vertices, shown through the circular symbols in FIG. 1, including a respective start vertex 122,142,162 and a respective end vertex 124,144,164 for each network. The vertices of each network are connected via a number of directed edges, with each directed edge connected between a respective source vertex and respective destination vertex in the network including that directed edge. Each directed edge is either an input-consuming directed edge or a non-input-consuming directed edge. An input-consuming edge allows a transition from its source vertex to its end vertex if the input (e.g. current input token) matches an input-consumption condition of that edge, after which that input is ‘consumed’, and the input proceeds to a next value in an input sequence (e.g. next input token). FIG. 1 illustrates some example input-consuming edges, discussed below. A non-input-consuming edge allows transition without ‘consuming’ an input. In FIG. 1, the non-input-consuming edges are epsilon transitions, which have no input-consumption condition attached and for which the transition can be made freely. These epsilon transitions are shown with ‘ε’ in FIG. 1. In some examples, a non-input-consuming edge might not be an epsilon transition. For example, a non-input-consuming edge might have an associated edge condition that might restrict transition unless the edge condition is satisfied.

For example, in FIG. 1 the first network 120 (‘Top’) includes a start vertex 122, which is connected by an input-consuming edge 1 to the start vertex 142 of the first embedded network 140 (‘Value’). The input-consuming edge 1 has an input-consumption condition ‘==START’. If the input (e.g. current input token) satisfies this input-consumption condition, i.e. is equal to ‘START’, then the transition is permitted and that input is ‘consumed’. Traversal through the RTN proceeds to that edge's destination vertex, which is the start vertex 142 of the first embedded network 140. The first network 120 also includes an input-consuming edge 6 with the input-consumption condition “==EOF” connected between the end vertex 144 of the first embedded network 140 and the end vertex 124 of the first network 120. If the input (e.g. current input token) satisfies this input-consumption condition, i.e. is equal to ‘EOF’, then the transition is permitted and that input is ‘consumed’. Traversal through the RTN proceeds to that edge's destination vertex, which is the end vertex 124 of the first network 120.

The first embedded network 140 (‘Value’) includes a start vertex 142, which is connected by a non-input-consuming edge 4 to the start vertex 162 of the second embedded network 160 (‘Array’). The first embedded network 140 also includes a non-input-consuming edge 12 connected between the end vertex 164 of the second embedded network 160 and the end vertex 144 of the first embedded network 140. Further, the first embedded network 140 includes a non-input-consuming edge 3 connected between the start vertex 142 and a first intermediate vertex 146. An input-consuming edge 13 with the input-consumption condition “==DIGIT” connects the first intermediate vertex 146 to a second intermediate vertex 148. If the input (e.g. current input token) satisfies this input-consumption condition, then the transition is permitted and that input ‘digit’ is ‘consumed’. Traversal through the RTN proceeds to that edge's destination vertex, which is the second intermediate vertex 148. The second intermediate vertex 148 is connected to the end vertex 144 of the first embedded network 140 via a non-input-consuming edge 15, and is also connected back to the first intermediate vertex 146 via a non-input-consuming edge 14.

The second embedded network 160 similarly includes first and second intermediate vertices 166,168, and a number of input-consuming edges and non-input-consuming edges as shown in FIG. 1. The second embedded network 160 includes a start vertex 162 and an end vertex 164. The start vertex 162 is connected via an input-consuming edge 7 to a first intermediate vertex 166, wherein the input-consuming edge has the attached input-consumption condition of ‘==OPEN_BRACKET’. In addition to the input-consuming edge 7, the first intermediate vertex 166 has another inbound input-consuming edge 10 from a second intermediate vertex 168, wherein the input-consuming edge 10 has the attached input-consumption condition of ‘==COMMA’. The first intermediate vertex 166 has an outbound non-input-consuming edge 8 to vertex 142 of the first embedded network 140 (i.e. the first embedded network's start vertex). The second intermediate vertex 168 has an inbound non-input-consuming edge 9 from vertex 144 of the first embedded network (i.e. the first embedded network's end vertex). The second embedded network 160 includes an input-consuming edge 11 with the attached input-consumption condition ‘==CLOSE_BRACKET’ that is outbound from the second intermediate vertex 168 and connects to the end vertex 164 of the second embedded network 160.

An RTN, such as the RTN 100 of FIG. 1, represents the rules of the relevant grammar graphically. It can be determined whether some input data formed from a stream of input tokens conforms to the grammar by parsing the input data. In the graphical RTN representation, each input-consuming edge represents a transition between its source vertex and its destination vertex conditional on the current input token of the input data matching the input-consumption condition associated with that input-consuming edge. For example, the transition from the start vertex 122 of the first network 120 (‘Top’) to the start vertex 142 of the first embedded network 140 is conditional on the current input token of the input data being “START”. Parsing of the input data advances to the next input token of the input data when the transition occurs.

Further, in the graphical RTN representation, each non-input-consuming edge represents an epsilon transition, which is a transition that is not conditional on the current input token of the input data and does not cause the parsing to advance to the next input token of the input data when the transition occurs.

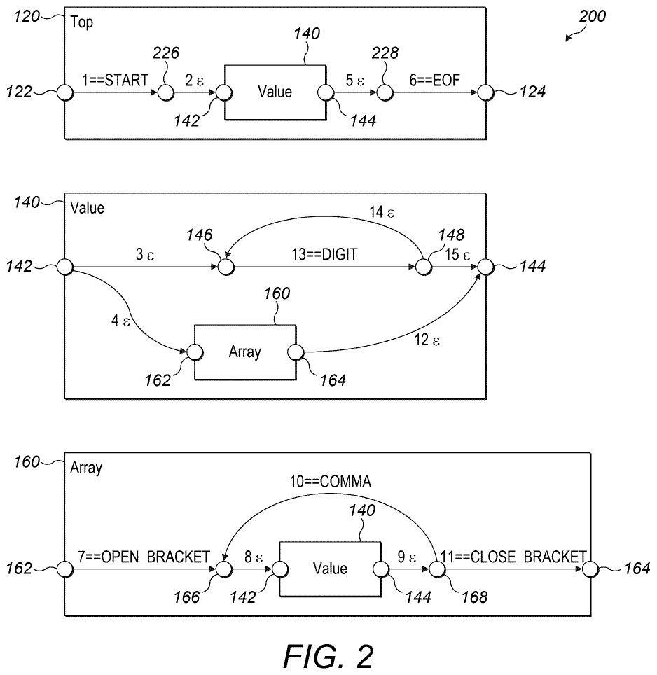

In an example, a modification can optionally be made to an initial RTN. This modification may be an optional preliminary step in a method of generating a hardware description for configuring a digital electronic circuit in accordance with the techniques of this disclosure. This modification involves processing a digitally stored version of the RTN 100. Various different formats may be used to digitally store the RTN. For example, a linked list of vertices and directed edges may be used to digitally store an RTN. The modification involves, if an edge connected to or from an embedded network is an input-consuming edge, inserting a new vertex and a new non-input-consuming edge between the input-consuming edge and the embedded network, such that all incoming and outgoing directed edges from the embedded networks are epsilon transitions. The step may include determining, for an edge connected to or from an embedded network, whether the edge is an input-consuming edge. If the edge is an input-consuming edge directed to the embedded network (i.e. the destination vertex of the input-consuming edge is a vertex of the embedded network), the RTN may be modified such that then input-consuming edge has the new inserted vertex as its destination vertex, and a new inserted edge is an epsilon transition between the new inserted vertex and the embedded network. If the edge is an input-consuming edge outgoing from an embedded network (i.e. the source vertex of the input-consuming edge is a vertex of the embedded network), the RTN may be modified such that then input-consuming edge has the new inserted vertex as its source vertex, and a new inserted edge is an epsilon transition between the embedded network and the new inserted vertex. The result of such a modification to the RTN 100 is shown in FIG. 2.

The RTN 200 of FIG. 2 is identical to the RTN 100 of FIG. 1, except that the first network 120 (‘Top’) in FIG. 2 includes an intermediate vertex 226 as the destination vertex of the input-consuming edge with the input-consumption condition “==START”, the intermediate vertex 226 itself being connected by a non-input-consuming edge to the start vertex 142 of the first embedded network 140. Additionally an intermediate vertex 228 is included as the destination vertex of a non-input-consuming edge from the end vertex 144 of the first embedded network 140, the intermediate vertex 228 being the source vertex for the input-consuming edge with the input-consumption condition “==EOF” connected to the end vertex 124 of the first network 120. The RTN 200 represents the same grammar as the RTN prior to this modification. The addition of these new vertices and edges does not change the grammar represented by the RTN but may offer advantages in generating a digital electronic circuit to parse data according to the grammar.

Such a modification can be made generally for any RTN, such that all incoming and outgoing directed edges from the embedded networks are non-input-consuming edges, i.e. epsilon transitions in particular. Further, for some RTNs this will already be the case, such that no modification is needed. In either case, an RTN having only epsilon transitions into and out of embedded networks is used to form the digitally stored graph from which the hardware description is generated in the methods described herein, as outlined in more detail below.

In the RTN of FIG. 2, each directed edge, both input-consuming and non-input-consuming has also been given numerical label. This is to aid understanding in the following description.

In an RTN having only epsilon transitions into and out of embedded networks, such as the RTN 200 of FIG. 2, for each network within which an embedded network is embedded, the non-input-consuming edge in that network that is connected to a start vertex of the embedded network will be referred to as an embedded-network-calling edge (or simply a calling edge). Similarly, the non-input-consuming edge in that network which is connected from the end vertex of the embedded network will be referred to as a corresponding embedded-network-returning edge (or simply a returning edge). In other words, for each embedded-network-calling edge and corresponding embedded-network-returning edge: the source vertex of the embedded-network-calling edge and destination vertex of the embedded-network-returning edge are vertices of the network within which the embedded network is embedded, the destination vertex of the embedded-network-calling edge is the start vertex of the embedded network, and the source vertex of the embedded-network-returning edge is the end vertex of the embedded network.

For example, the non-input-consuming edge (epsilon transition) labelled 2 in the first network 120 in FIG. 2 is a first-embedded-network-calling edge, and the non-input-consuming edge labelled 5 in FIG. 2 is a corresponding first-embedded-network-returning edge. Similarly, the non-input-consuming edge labelled 8 in FIG. 2 in the second embedded network 160 is a first embedded-network-calling edge, and the non-input-consuming edge labelled 9 is a corresponding first embedded-network-returning edge.

Further, the non-input-consuming edge labelled 4 in the first embedded network 140 in FIG. 2 is a second embedded-network-calling edge, and the non-input-consuming edge labelled 12 in the first embedded network 140 in FIG. 2 is a corresponding second embedded-network-returning edge.

Using the above-described terminology, a method of generating a hardware description for configuring a digital electronic circuit to parse input data against the example grammar above will now be described, the method in accordance with the techniques of this disclosure.

The method begins with the digitally stored RTN 200 of FIG. 2, i.e. having embedded-network-calling and embedded-network-returning edges that are epsilon transitions. The method enables the implementation of this RTN as a digital electronic circuit by generating a hardware description for the digital electronic circuit.

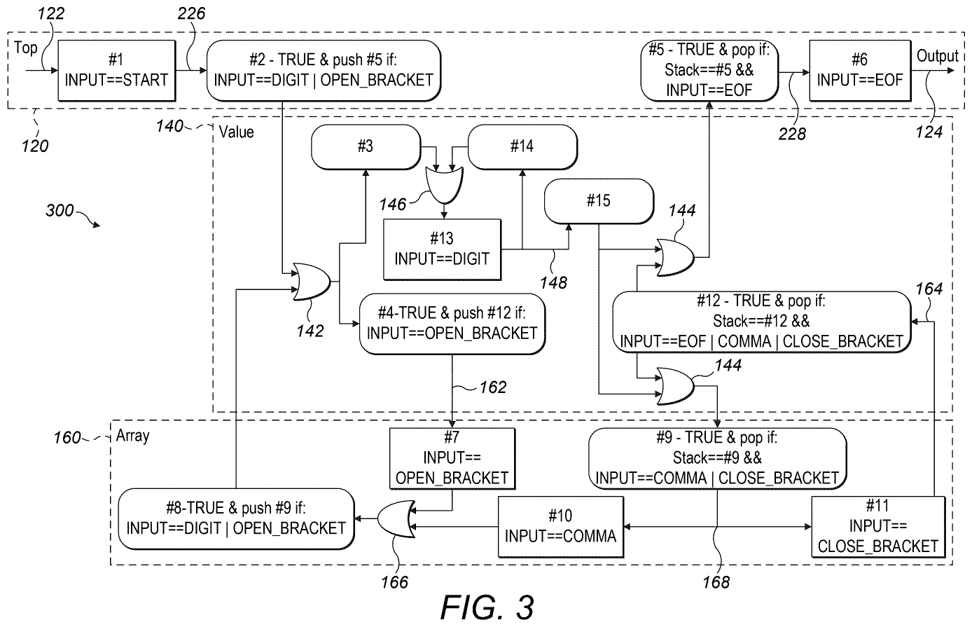

FIG. 3 shows a schematic logical diagram of a digital electronic circuit 300 created according to the hardware description generated based on the RTN 200.

In the method, instructions for an input buffer in the digital circuit (not shown in FIG. 3) are included in the hardware description. In the digital electronic circuit, the input buffer stores the sequence of input tokens of the input data, and sequentially outputs each input token in sequence, the input buffer providing a current input token as output until a next clock tick.

Instructions for circuitry corresponding to each of the edges and each of the vertices of the RTN 200 are also included in the hardware description. The circuitry for each directed edge in the RTN 200, both input-consuming and non-input-consuming, is shown in FIG. 3 as a block having the same numerical label as the numerical label of the corresponding edge in FIG. 2. The circuitry for each vertex is shown in FIG. 3 as a connection between block, using the same reference numeral as used for the corresponding vertex in FIG. 2. The circuitry conforms to the following rules based on the RTN.

Firstly, the circuitry for each vertex is electrically connected to the corresponding circuitry for each edge that is connected to that vertex in the RTN 200. Further, the circuitry for each vertex outputs a logical high (e.g. a voltage representative of a logical high) to circuitry for all outgoing directed edges of that vertex (i.e. all edges for which that vertex is a source vertex) if circuitry for any incoming directed edge of that vertex (i.e. any edge for which that vertex is a destination vertex) provides a logical high. In other words, the circuitry for that vertex conveys a logical high from any incoming directed edge to all outgoing directed edges of that vertex.

For example, in the case of the intermediate vertex 226 in the first network 120 (‘Top’) of RTN 200 between the input-consuming edge labelled 1 and the non-input-consuming edge labelled 2, the circuitry for that vertex is an electrical connection that outputs a logical high to the circuitry for the non-input-consuming edge 2 when a logical high is received from circuitry for the input-consuming edge 1. This electrical connection may simply be a wire or plain conductor or the like in the digital electronic circuit. The hardware description would therefore include instructions for a plain conductor connection between the circuitry for input-consuming edge 1 and the circuitry for non-input-consuming edge 2.

In the case where the vertex has multiple outgoing directed edges, such as the intermediate vertex 148 in the first embedded network 140 (‘Value’) of RTN 200, the circuitry for the vertex outputs a logical high to the circuitry for all outgoing edges when the circuitry for the vertex receives a logical high. For example, the hardware description could include instructions for a plain conductor connection between the circuitry for input-consuming edge 13 and the circuitry for both non-input-consuming edge 14 and non-input-consuming edge 15.

Further, in the case where a vertex has multiple incoming directed edges, such as the intermediate vertex 146 in the first embedded network 140 (‘Value’) of RTN 200, the circuitry for the vertex outputs a logical high to the circuitry for all outgoing edges when it receives a logical high voltage signal from any of the circuitry for the incoming edges. This can be achieved using a logical OR gate in the vertex circuitry. For example, the hardware description could include for intermediate vertex 146 instructions for an OR gate having its input terminals connected to the circuitry for the non-input-consuming edges 3 and 14, and its output terminal connected to the circuitry for the input-consuming edge 13. In this way, the circuitry for input-consuming edge 13 receives a logical high whenever the circuitry for either of non-input-consuming edges 3 or 14 provides a logical high.

For vertices with multiple incoming edges that also have multiple outgoing edges, the output terminal of the OR gate is connected to the circuitry for each outgoing edges to output a logical high voltage signal to the circuitry for all outgoing edges when the circuitry for the vertex receives a logical high.

In some examples, a vertex with multiple incoming edges and multiple outgoing edges can be implemented using multiple OR gates, wherein circuitry for only some of the outgoing edges is connected to any one of the multiple OR gates.

In the RTN 200 shown in FIG. 2, end vertex 144 has both multiple incoming directed edges and multiple outgoing directed edges. In the digital electronic circuit shown in FIG. 3, the circuitry for end vertex 144 is shown separated into two separate OR gates, with a respective OR gate for each of the outgoing edges of end vertex 144. Each OR gate outputs a logical high to the circuitry for one of the outgoing directed edges (i.e. non-input-consuming edges 5 and 9). However, these two OR gates could instead be combined as a single OR gate having two outputs in some embodiments, as mentioned above. These two configurations are equivalent. Separating the vertex circuitry for a vertex with multiple outgoing edges in this way may be advantageous for routing purposes, whether in the hardware description or in a digital electronic circuit configured according to the hardware description.

Thus a vertex in the RTN 200 is included in the hardware description as an instruction to implement a logical OR for all of the incoming edges of that vertex, with the logical OR for a single incoming edge being a simple wire or plain conductor in some examples because the logical OR of a single input is the same as the input.

The circuitry for each input-consuming edge (shown as rectangular blocks in FIG. 3) receives the input token of the input data presently output by the input buffer. The circuitry for each input-consuming edge includes logical circuitry that compares this current input token with the input-consumption condition associated with that input-consuming edge. The circuitry for each input-consuming edge also includes a register. If the current input token output by the buffer is found to match the input-consumption condition associated with that input-consuming edge by the logical circuitry, and if in addition the circuitry for the source vertex of that input-consuming edge is outputting a logical high voltage signal, the register in the circuitry for that input-consuming edge will, on the next clock tick, provides a logical high to the circuitry for the destination vertex of that input-consuming edge until the end of the next clock cycle.

For example, in the RTN 200 of FIG. 2, the input-consumption condition associated with the input-consuming edge 1 is “==START”, meaning the current input token of the input data must be equal to START. On a first clock tick, the buffer provides START as its output, wherein START is the first input token in the input data. This first input token is provided to the circuitry for each of the six input-consuming edges, i.e. input-consuming edges 1, 6, 7, 10, 11 and 13. Only input-consuming edge 1 has an input-consumption condition “==START” matching this first input token. Therefore the register in the circuitry for input-consuming edge 1 will output a logical high (if a logical high is also provided as input to the register, which may be an initial signal to initiate the parsing process or may be hardwired). The register in the circuitry will output this logical high signal on the next clock tick, i.e. on a second clock tick, and will continue to output this logical high signal for the entire clock cycle (i.e. until a third clock tick). Also on the second clock tick, the input buffer advances to output DIGIT as the second input token in the input data. The register in the circuitry for input-consuming edge 1 will stop outputting a logical high at the next clock tick (third clock tick) because the current input token is DIGIT rather than START and so this edge's input-consumption condition is no longer satisfied. Only input-consuming edge 13 has an input-consumption condition “==DIGIT” matching this second input token. Because of this match, the register in the circuitry for input-consuming edge 13 would output a logical high at the next clock tick (third clock tick), provided that the circuitry for input-consuming edge 13 also receives a logical high from the circuitry of its source vertex (i.e. it receives a logical high signal from the output of the OR gate in the circuitry for intermediate vertex 146), which it does if the preceding input token was START.

The circuitry for each non-input-consuming edge (shown as blocks with rounded corners in FIG. 3) includes a coupling between circuitry for the source vertex of that non-input-consuming edge and circuitry for the destination vertex of the non-input-consuming edge.

In the case of non-input-consuming edges that are not embedded-network-calling or embedded-network-returning edges, such as non-input-consuming edges 3, 14, 15 in FIG. 2, this coupling may simply be a wire or other conductor or the like. If a logical high is received from the circuitry for the source vertex, the logical high is provided to the circuitry for the destination vertex.

In the case of embedded-network-calling edges and embedded-network-returning edges (also referred to as ‘calling edges’ and ‘returning edges’ for brevity), i.e. non-input-consuming edges 2, 4, 5, 8, 9, 12, the coupling includes combinational (non-registered) logic configured to perform a number of additional acts, as outlined below.

Instructions for a memory in the digital circuit (not shown in FIG. 3) are included in the hardware description. In the digital electronic circuit, the memory is configured to store a value and provide the stored value as output from the memory. In this example, the memory is a stack. The output from the memory is the value at the top of the stack.

For the calling edges, a call from a network to an embedded network (e.g. from ‘Top’ to ‘Value’) requires pushing to the top of the stack the identity of the returning edge that will be followed on return from that embedded network (referred to as the “corresponding” returning edge for each specific calling edge). Further, there is performed a check that the current input token provided by the buffer will be consumed by one of the immediately subsequent input-consuming edges that follows the calling edge in the RTN, i.e. is downstream from the destination vertex of the calling edge (the start vertex of the embedded network). By ‘consumed’, it is meant that the input-consumption condition of that input-consuming edge will match the current input token and cause the input-consuming edge to provide a logical high when a logical high provided from the calling edge propagates through the circuit to that input-consuming edge. For example, in the RTN of FIG. 2, the next input-consuming edge downstream from the calling edge labelled 2 is either input-consuming edge 13 or input-consuming edge 7. Similarly, the next input-consuming edge downstream of the calling edge labelled 4 is the input-consuming edge 7.

Therefore, the logic in the circuitry for each calling edge receives the input token of the input data that is currently provided by the input buffer. The logical circuitry of each calling edge is configured to compare this current input token with the input-consumption conditions associated with the next input-consuming edge/edges downstream of the destination vertex of that calling edge. If the input token matches an input-consumption condition of one of these next input-consuming edges for that calling edge, and additionally if the circuitry for the source vertex of that calling edge provides a logical high, then logical circuitry for that calling edge provides a logical high to the circuitry for the destination vertex of that calling edge, and also pushes to the top of the stack a value indicative of the corresponding returning edge for that calling edge. The corresponding returning edge represents the returning edge to be followed on exit from the embedded network when entered from the calling edge. By storing a value indicative of the corresponding returning edge, this information can be used to ensure that the embedded network is exited to a correct corresponding returning edge, which may be advantageous if the embedded network is callable from multiple locations within the RTN. By using a stack for this purpose, nested levels of embedded networks may be called and returned from in an appropriate sequence.

Using the calling edge labelled 2 in RTN 200 as an example, if the circuitry for the intermediate vertex 226 outputs a logical high to the circuitry for calling edge 2, and if the current output from the buffer is either DIGIT or OPEN_BRACKET, then the combinational logic in the circuitry for calling edge 2 outputs a logical high to the circuitry for the start vertex 142 of the first embedded network 140, and pushes to the stack a value indicative of the returning edge labelled 5 in FIG. 2.

In some embodiments, each directed edge in the RTN may be given an identifier, such as the labelling numbers in FIG. 2, and these identifiers may be used as the values indicative of the returning edges. The identifiers may optionally be unique such that no two edges in the RTN have the same identifier. Alternatively, in some examples only certain edges have an identifier, such as only those edges that are calling or returning edges have identifiers, or only those edges that are returning edges have identifiers. Some practical implementations may provide all edges with identifiers as a consequence of digitally storing a graph representing the RTN.

Similarly, for the returning edges, a return from an embedded network to the network in which it is embedded (e.g. from ‘Value’ to ‘Top’) requires a check that the value indicative of that returning edge is present at the top of the stack as the output of the memory. There is also performed a check that the current input token output by the buffer will be consumed by (match the input-consumption condition of) one of the immediately subsequent input-consuming edges that is downstream of the returning edge in the RTN. If these returning-edge conditions are met, the value indicative of that returning edge is popped from the top of the stack. In determining whether an input-consuming edge is immediately subsequent/downstream of a returning edge, any non-input-consuming edges that represent epsilon transitions between the returning edge and an input-consuming edge may be disregarded because a logical high may be considered to propagate unconditionally through the epsilon transitions.

Therefore the logic in the circuitry for each returning edge receives the input token of the input data currently provided as output by the input buffer. The logic compares this current input token with the input-consumption conditions associated with the next input-consuming edge/edges downstream of the destination vertex of the returning edge. If the input token matches an input-consumption condition of one of these next input-consuming edges, and additionally if the circuitry for the source vertex of that returning edge provides a logical high, and additionally if the value at the top of the stack is indicative of that returning edge, then the logical circuitry for the returning edge provides a logical high to the circuitry for the destination vertex of that returning edge and pops the value indicative of that returning edge from the stack. Thus each call to an embedded network from a calling edge pushes a value to the stack and each return from an embedded network from a returning edge pops a value from the stack. By checking the value at the top of the stack and confirming it to be indicative of the returning edge, nested embedded networks may be called and returned from in the appropriate sequence, even with direct or indirect recursion.

Using the returning edge labelled 5 in RTN 200 as an example, if the circuitry for the end vertex 144 of the first embedded network 140 outputs a logical high to the circuitry for calling edge 5, and if the present output from the buffer is EOF, and if the value at the top of the stack is indicative of returning edge 5, then the combinational logic in the circuitry for returning edge 5 outputs a logical high signal to the circuitry for the intermediate vertex 228.

As mentioned, FIG. 3 shows the resulting digital electronic circuit configured according to the hardware description generated by applying all of the above rules to the RTN 200 of FIG. 2. In other words, FIG. 3 shows the RTN 200 of FIG. 2 implemented in a digital electronic circuit. The hardware description specifies the logical arrangement of elements of the digital electronic circuit that implements the RTN.

A hardware description generated by a method in accordance with the techniques disclosed herein may be expressed in any suitable hardware description language (HDL), for example, using VHSIC Hardware Description Language (VHDL) or Verilog. This hardware description may be used to create a digital electronic circuit, such as by synthesizing a configuration for an FPGA device, or creating a layout for an ASIC (e.g. using electronic design automation software tools). In other embodiments, the hardware description may be generated directly in the form of a netlist, i.e. without generating a hardware description in a hardware description language as an intermediate representation of the digital electronic circuit. In some embodiments, generating a hardware description in a hardware description language or in the form of a netlist may comprise generating the hardware description using a hardware description language and a netlist in combination.

The hardware-implemented RTN in the digital electronic circuit of FIG. 3 can be used to parse input data in the form of a stream of input tokens against the grammar associated with the RTN. An example parsing process will now be described based on FIG. 3.

Firstly, the input data is stored in the input buffer, and the first input token in the input data is output from the buffer at the start of the parsing operation, i.e. on a first clock tick. The buffer then sequentially outputs, on each clock tick, each input token in the input data. The input token may be held as output from the input buffer for the duration until the next clock tick; in the meantime, the input token is provided to other elements of the digital electronic circuit, such as circuitry for input-consuming edges.

The current input token that is the output of the buffer is, until a next clock tick, provided to the logic in the circuitry for each input-consuming edge, each calling edge, and each returning edge. In the present example, the first input token is START, which is provided as output by the buffer on a first clock tick. The logic in the circuitry for each edge compares this input token with the input-consumption condition associated with that edge. Here, only input-consuming edge 1 has the input-consumption condition “INPUT==START”. Therefore the register in the circuitry for input-consuming edge 1 will, upon the next (second) clock tick, go high and output a logical high to the circuitry for non-input-consuming edge 2, via the circuitry for vertex 226. The circuitry for all other edges will not provide a logical high after the second clock tick.

The buffer then moves on to the next input token, on the second clock tick. The next input token is DIGIT. This input token matches the input-consumption condition for input-consuming edge 13 but the circuitry for input-consuming edge 13 is not yet receiving a logical high from the circuitry for vertex 146, and so will not yet output logical high upon the next (third) clock tick. Non-input-consuming (calling) edges 2 and 8 both also check for the input-consumption condition “INPUT==DIGIT”. The circuitry for calling edge 8 is not receiving logical high from the circuitry for vertex 166, and so does not output logical high. But, the circuitry for calling edge 2 is receiving a logical high from the circuitry for vertex 226, and so the circuitry for calling edge 2 provides a logical high to the circuitry to the circuitry for vertex 142. The circuitry for calling edge 2 also pushes to the stack a value indicative of the corresponding returning edge for that calling edge, which in this case is returning edge 5.

During the same clock cycle (i.e. before the third clock tick), the logical high output by the circuitry for calling edge 2 propagates to the OR gate in the circuitry for vertex 142, causing the OR gate to output logical high to the circuitry for both non-input-consuming edge 3 and non-input-consuming (calling) edge 4. For non-input-consuming edge 4, the present input token DIGIT does not match the calling-edge condition “INPUT==OPEN_BRACKET”, and so the circuitry for non-input-consuming edge 4 does not output logical high. However, non-input-consuming edge 3 is an epsilon transition, and not a calling or returning edge, and therefore the circuitry for non-input-consuming edge 3 may be a simple coupling. The coupling of non-input-consuming edge 3 propagates the logical high signal to the circuitry for vertex 146, which in turn propagates the signal to the circuitry for input-consuming edge 13.

Input-consuming edge 13 now receives a logical high, and the input-consumption condition “INPUT==DIGIT” is matched by the current input token, therefore the circuitry for input-consuming edge 13 will output a logical high to the circuitry for vertex 148 after the next (third) clock tick. The propagation of the logical high signal through the digital electronic circuit 300 then pauses until the next clock tick.

On the next (third) clock tick, the buffer outputs the next input token, which in this case is EOF. The circuitry for input-consuming edge 13 outputs a logical high, which propagates via the circuitry for non-input-consuming edge 15 and the circuitry for vertex 144, and is therefore provided as input into the circuitry for each of non-input-consuming edges 5 and 9. The input token EOF does not match the calling-edge condition “INPUT=COMMA” or “INPUT=CLOSE_BRACKET” checked for by the circuitry for non-input-consuming edge 9, and therefore the circuitry for non-input-consuming edge 9 does not allow propagation of a logical high signal. Non-input-consuming edges 5 and 12 check for the condition “INPUT==EOF”. The circuitry for non-input-consuming edge 12 is not receiving logical high from the circuitry for vertex 164, and therefore does not provide a logical high as output. The circuitry for non-input-consuming (returning) edge 5 is receiving a logical high from the circuitry for vertex 144. The circuitry for returning edge 5 therefore checks the stack (peeks at the top value on the stack) to ensure that a value indicative of the returning edge 5 is at the top of the stack. This is the case here, and so the circuitry for returning edge 5 pops that value from the stack, and outputs a logical high to the circuitry for vertex 228, which propagates the logical high to the circuitry for input-consuming edge 6. The input-consumption condition of input-consuming edge 6 “INPUT==EOF” is matched by the present input token, and therefore the register in the circuitry for input-consuming edge 6 will go high after the next (fourth) clock tick. The propagation of the logical high signal through the digital electronic circuit 300 then pauses until the next clock tick.

On the next (fourth) clock tick, the circuitry for input-consuming edge 6 outputs logical high to the circuitry for end vertex 124. When a logical high is detected at the output of the digital electronic circuit, i.e. the circuitry for the end vertex for the entire RTN (in this case end vertex 124), it can be concluded that the input data has successful parsed, and therefore the input data conforms to the grammar, provided that the logical high at the output occurs coincidently with the end of sequence of input tokens (i.e. when the last of the input data is or has been consumed). In the present example, on the fourth clock tick, the buffer does not include any input tokens which it can output, as the final token EOF was output on the previous (third) clock tick, and therefore the input-consumption condition of the end of the sequence of input token is met at the same time as the output of the digital electronic circuit going to logical high. It can therefore be concluded that the specific input data conforms with the data format corresponding to the grammar upon which the RTN is based. In the present example, the input data was START DIGIT EOF, which is an allowable stream of input tokens according to the grammar and RTN 200 of FIG. 2.

Regardless of the input data that is used, the logical high signal can only propagate through the digital electronic circuit to the output of the digital electronic circuit coincidently with the last input token (i.e. when the last of the input data is or has been consumed) if the input data is or has been successfully parsed against the grammar. Therefore any arbitrary input data can be processed using the digital electronic circuit to determine if it conforms with the grammar. Input data that does not conform with the grammar is not successfully parsed and the logical high signal does not propagate to the output of the digital electronic circuit coincidently with the last input token. Therefore a digital electronic circuit produced according to the techniques of this disclosure may be able to determine whether or not input data conforms with the grammar upon which the RTN is based, and therefore whether or not the input data conforms with the data format (such as a particular JSON schema, for example) that the grammar defines. This may offer advantages for the large-scale processing of data because digital electronic circuits according to the techniques of this disclosure may be employed to check data prior to subsequent processing, which may reduce inefficiencies due to malformatted data and may allow rejection of data that potentially includes malicious code. Further, this check is performed using a digital electronic circuit, such as an FPGA. An FPGA by default is not a Turing-complete machine and so cannot be caused to execute arbitrary code such as any malicious code in the input data to be parsed. Therefore the techniques of this disclosure may offer security advantages compared with parsing input data using software running on a general-purpose computer.

As discussed above, the purpose of the pushing to the stack by the calling edge circuitry, and the checking (peeking) and popping by the returning edge circuitry, is to keep track of which embedded network of the RTN the propagating logical high signal is currently in during the parsing. In other words, the output of the digital circuit can only be a logical high, indicating a successful parse, if the correct number of calls and returns between embedded networks has been made. For example, the input data START OPEN_BRACKET DIGIT EOF is not allowed by the grammar of RTN 200 of FIG. 2, as the necessary CLOSE_BRACKET is missing between DIGIT and EOF. However, during the parsing of this input data by the digital circuit, when the buffer outputs the DIGIT input token, a logical high voltage signal is received by the circuitry for non-input-consuming (returning) edge 5 after the next clock tick. Without the stack check, when the next input token EOF is output by the buffer, the non-input-consuming edge 5 would output logical high, which would result a logical high output at the circuitry for vertex 124, indicating a successful parse. The stack check ensures that after moving in the RTN 200 from the second embedded network 160 (‘Array’) into the first embedded network 140 (‘Value’), a return is made back to the second embedded network 160 (‘Array’) as is required by the grammar, rather then jumping straight from the first embedded network 140 (‘Value’) to the first network 120 (‘Top’). If the stack check fails, i.e. a value for that returning edge is not at the top of the stack, then logical high signal cannot propagate past the circuitry for the returning edge and thus a false positive validation result is prevented. However, as discussed below, the use of a stack is not essential for this function, particularly if it is known that an embedded network can only be called once during a parsing process before returning from that embedded network; in such cases the stack is unnecessary because there is no need to keep track of how many times the embedded network has been called and the particular calling edge and corresponding returning edge the embedded network has been called each on each occasion. The skilled reader will recognise that other memory hardware may be used to store the value for a returning edge in such circumstances, such as a register.

### Memory Implementation

The memory in the digital circuit specified by the hardware description may be implemented in a number of different ways. The memory is a stack in the example discussed above.

In some examples, a single ‘global’ stack may be used for all calling and returning edges. In other words, the circuitry for each calling edge is configured to push the value indicative of its corresponding returning edge to the top of a single stack shared by all of the calling edges, and the circuitry for each returning edge peeks from and pops from the same stack.

In some examples, it may be necessary for multiple hardware components of a digital electronic circuit to access the stack for pushing, peeking or popping within a single clock cycle. For example, in FIG. 3, if the current input token output by the buffer is CLOSE_BRACKET, and the circuitry for input-consuming edge 11 is receiving a logical high from the circuitry for vertex 168, the register in the circuitry for input-consuming edge 11 will go high at the next clock tick, providing a logical high to the circuitry for non-input-consuming edge 12. If the next token output by the buffer is EOF, a peek and pop of the top value of the stack must be sequentially performed by the circuitry for non-input-consuming (returning) edge 12 and also by the circuitry for non-input-consuming (returning) edge 5, in order for a logical high signal to reach the circuitry for input-consuming edge 6. Such a situation may be addressed in multiple ways. For example, the digital electronic circuit may be configured to queue stack operations, and ensure that such stack operations are processed before a next clock tick. This can be done by configuring stack operations to run faster than the clock speed that is used for the processing of input tokens from the buffer, in order to permit multiple stack operations to take place in sequence (e.g. peeking or popping or pushing to a single stack from multiple locations in the digital electronic circuit) between each advance of the buffer output. Other embodiments include a mechanism to temporarily pause the processing of input tokens for one or more clock cycles and maintain logic values around the circuit until the required sequence of stack operations is complete.

Alternatively, one or more distributed local stacks may be used instead of or in addition to a global stack. In some embodiments, a local stack is provided for each embedded network of the RTN. The circuitry for each calling edge to a specific embedded network would push to the local stack for that embedded network, and the circuitry for each returning edge from that specific embedded network would peek and pop from the local stack for that embedded network.

To implement local stacks in the example of FIGS. 2 and 3, the hardware description could include instructions for two stacks: a first local stack corresponding to the first embedded network (‘Value’) 140, and a second local stack corresponding to the second embedded network (‘Array’) 160. The circuitry for calling edges 2 and 8 would be configured to push to the first stack, and the circuitry for returning edges 5 and 9 would be configured to peek and pop from the first stack. Similarly, the circuitry for calling edge 4 would push to the second stack, and the circuitry for returning 12 would peek and pop from the second stack.

Distributed local stacks may provide technical advantages relative to the use of a global stack. Distributed local stacks may reduce or avoid the need for multiple returning edges or calling edges to access a single stack in a single clock cycle, which can mean that the digital electronic circuit can be implemented without circuitry to pause the processing or ensure that multiple stack operations take place using a single stack in a single cycle, which may result in a more efficient hardware implementation or allow for greater data throughput. For example, for the path from non-input-consuming edge 12 to non-input-consuming edge 5 to input-consuming edge 6 discussed above for the global stack, which requires two stack pops, both stack pops may be performed at the same time using separate local stacks. Specifically, the peek and pop by the circuitry for the returning edge 12 can be performed at the first local stack at the same time and in the same clock cycle as the peek and pop by the circuitry for the returning edge 5 using a different local stack.

Thus having multiple stacks that can each be modified in a single clock cycle can lead to improved parsing performance, by avoiding stack-access bottlenecks that could occur with a global stack. The parsing performance may be improved because the digital electronic circuit can operate at a higher clock speed or can avoid a pausing and queuing mechanism as described above.

In addition, the use of distributed local stacks may avoid the need for large combinational logic functions for stack push, peek and pop operations in the circuitry for the calling and returning edges. Larger combinational logic functions reduce the maximum viable clock speed for the digital electronic circuit, and therefore further limit the speed at which data can be parsed in the digital electronic circuit.

Moreover, local stacks for each embedded network can be located more optimally within the digital electronic circuit, such as nearby to the circuitry for calling edges and returning edges that access the local stack. By contrast, a single global stack can only be located at one position within the digital electronic circuit, leading to a more topologically complicated routing of paths and physically longer conductive paths in the digital electronic circuit, which can increase propagation times between circuit elements and further reduce the maximum clock speed.

Moreover, the use of multiple local stacks may require a smaller amount of storage in total, relative to a global stack, and therefore may be more efficient to implement. This is because each local stack may only require enough storage to represent the total number of calling contexts for its associated embedded network.

The advantages of multiple distributed local stacks compared to a single global stack may be more pronounced for larger and/or more complex grammars.

In some examples, the digital electronic circuit may use a combination of one or more local stacks and one or more global or ‘shared’ stacks. For example, the digital electronic circuit may use a respective local stack for each of one or more embedded networks, and well as one or more shared stacks that are each used by multiple other embedded networks.

In recursive calling contexts, there might be no limit to the number of times that an embedded network could be recursively called within itself. Because of this, an infinite stack depth would be needed to facilitate all possible input data that conforms to the grammar. For practical implementations, whenever a stack is used in a recursive context, a stack depth must be chosen that limits the number of nested recursive calls that can be made. In such a case, the limit would prevent a digital electronic circuit from parsing the recursive calling of this embedded network a number of times greater than the stack depth. Therefore the parse would fail if the stack depth limit is or would be exceeded, e.g. if a value is pushed to a stack that is already full.

While some embodiments employ a stack, other embodiments include calling and returning edges that are not implemented using a stack. In some embodiments, if an embedded network in the RTN always returns before it is called again, a simpler memory implementation such as a register is used instead of a local stack for that embedded network. Specifically, if an embedded network cannot be called a second time after a first call, unless a return has been made following the first call, then the stack is only required to have a stack depth of one. This situation may arise where an embedded network is embedded at one or more locations within an RTN, but the embedded network is not embedded within itself, either directly or indirectly. Therefore the memory to store a value indicative of a returning edge from that embedded network may be implemented as a register.

### Inlining Embedded Networks

In some examples, one or more embedded networks may be ‘inlined’ in the generated hardware description and any corresponding digital electronic circuit implemented based on the hardware description. ‘Inlining’ comprises a processing operation performed on a digitally stored RTN before generating a hardware description based on the RTN in which one or more embedded networks are ‘inlined’. The use of the term ‘inlining’ in the present application is analogous to its use in software optimisation, where the calling of a function at a location in code is replaced by the content of that function at that location. If an embedded network is inlined then that embedded network is not called from the network within which it is embedded but instead its content is inserted directly into the network within which that embedded network was embedded.

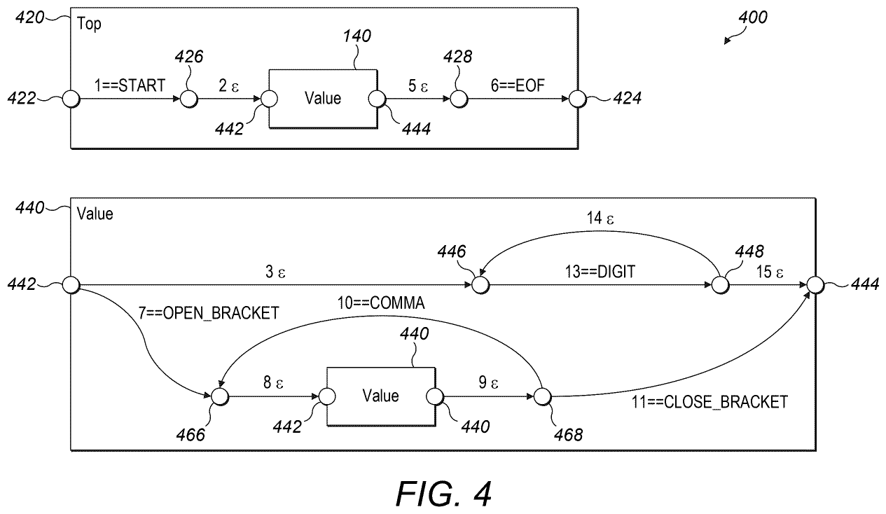

For example, in cases where an embedded network is only called in a single context, i.e. at only one location in the RTN, that embedded network can be inlined. In the RTN 200 of FIG. 2, the second embedded network 160 (‘Array’) is only called from the first embedded network 140 (‘Value’). Therefore the second embedded network 160 can be subsumed into first embedded network 140. FIG. 4 shows the RTN resulting from this process. The RTN 400 shown in FIG. 4 is identical to RTN 200 of FIG. 2, except for the inlining of the second embedded network 160 (‘Array’). The non-input-consuming edges 4 and 12, which were added in FIG. 2 to ensure that the calling and returning edges in the RTN 200 were epsilon transitions, have been removed in the RTN 400 of FIG. 4. This is because there are no longer calling or returning edges for the second embedded network 160 (‘Array’) of FIG. 2. The RTN 400 of FIG. 4 has epsilon transitions for the calling and returning edges 2 and 5 for the embedded network 440 (‘Value’). Analogous reference numerals have been used for the RTN 400 of FIG. 4.

The RTN 400 of FIG. 4 represents the same grammar as the RTN 200 of FIG. 2 but contains fewer overall directed edges and vertices and fewer calls and returns from embedded networks. Therefore the digital electronic circuit implementing the RTN 400 may advantageously require less logical circuitry due to the inlining performed, as well as less memory due to the lower number of calls/returns and thus lower requirements to store values indicative of returning edges.

A hardware description can be generated for the RTN 400 using the same steps and rules as outlined above for FIGS. 2 and 3, allowing the RTN 400 to be implemented as a digital electronic circuit to perform parsing according to the grammar upon which the RTN 400 is based.

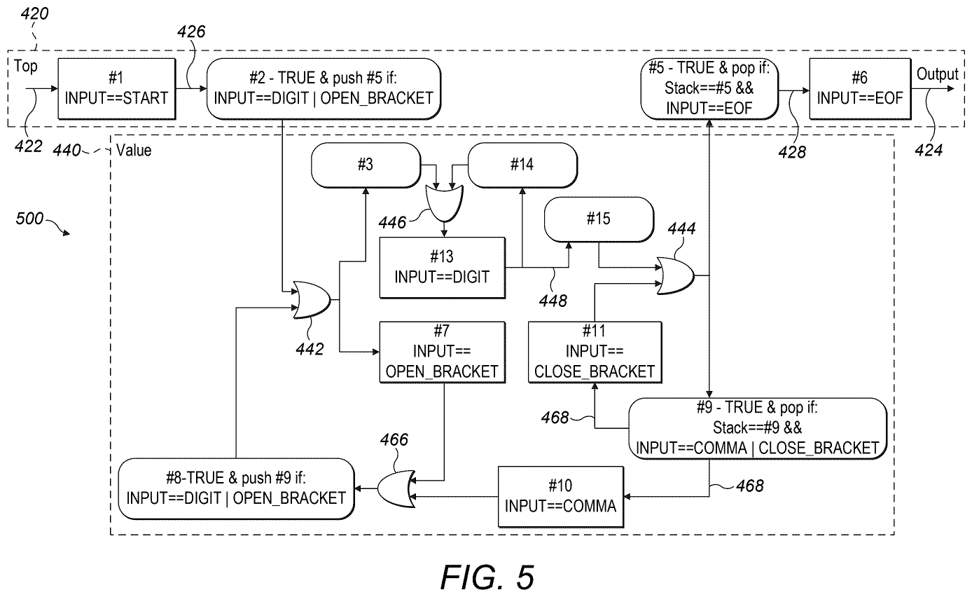

FIG. 5 shows a schematic logical diagram of a digital electronic circuit 500 according to the hardware description generated from the RTN 400 upon which inlining has been performed in accordance with the above-described steps. The operation of digital electronic circuit 500 is analogous to the operation of the digital electronic circuit 300 of FIG. 3, although may provide advantages relative to digital electronic circuit 300 in terms of reduced amount of logical circuitry and/or reduced memory requirements.

For embedded networks that are called in multiple contexts, i.e. called at multiple different locations in the RTN, such embedded networks can still be inlined. However, inlining such embedded networks only provide inlining benefits at the location at which they are inlined. Therefore for the greatest inlining benefit, such embedded networks are inlined at each location in the RTN separately. This means that the circuitry implementing the embedded network in the digital electronic circuit must be included separately for each calling context, i.e. at each relevant location within the circuit. In practice there may be a limit to the size or number of components of a digital electronic circuit, which may limit the degree to which inlining may be performed. Moreover, inlining recursively called embedded networks faces additional restrictions as discussed below.

In general, inlining an embedded network that is called from multiple different locations at those multiple different locations may be particularly advantageous if that embedded network is relatively small, such that the increased circuitry caused by the inlining at multiple different locations remains relatively small, although larger embedded networks may be inlined if the resulting digital electronic circuit would remain within size limits.

Inlining may also be used for an embedded network in a recursive calling context. However, physical constraints would prevent an embedded network being recursively inlined a number of times without limit. For example, in the RTN 400 of FIG. 4, there is no limit to the number of times that the embedded network 440 (‘Value’) could be recursively called within itself, and therefore no limit to the number of times the embedded network 440 (‘Value’) could be inlined. In a practical implementation, a recursion limit must be chosen (in the same way that a stack depth must be chosen when using a stack to keep track of calls and returns to/from a recursively embedded network). The recursion limit may be a predetermined maximum recursion depth that is the maximum number of times that a recursively called embedded network may be inlined within itself. The recursion limit might be a number such as five or ten, although the particular number used may depend on hardware constraints of the digital electronic circuit, such as FPGA capacity. The recursion limit may permit the embedded network 440 to be inlined within itself a maximum of five ten times. In some examples, the data format might specify a maximum number of levels of recursion and so requirements for inlining a recursively embedded network may be known when generating the hardware description and decisions on whether or not to inline an embedded network and a number of levels of inlining to perform may be made based on this knowledge.

### Calling/Returning Edge Optimisation

In some embodiments, optimisations can be made to the logic in the calling and returning edges.

For the calling edges described above, a call from a network to an embedded network requires storing in memory (e.g. a stack or a register) the identity of the corresponding returning edge that will be followed on return from that embedded network. There is performed a check that the current input token provided by the buffer will be consumed by (i.e. match the input-consumption condition of) one of the immediately subsequent (downstream) input-consuming edges that follow the calling edge in the RTN.

In some situations, an optimisation may be made to omit the check that the current input token provided by the buffer will be consumed by one of the immediately subsequent input-consuming edges. In a resulting digital electronic circuit, an incoming logical high signal to the circuitry for the calling edge is always propagated and the identity of the corresponding returning edge stored in memory.

This optimisation to omit a check of the input token being consumed downstream of the corresponding returning edge is not required in the case where there is no alternative transition to the calling edge that could progress the parse. Specifically, the check that the input token will be consumed downstream of the corresponding returning edge is not required if there are no other edges competing with a calling edge in the RTN to continue the parse, i.e. there are no other edges sharing the same source vertex as the calling edge (and therefore no other edges branching off from the same source vertex as the calling edge). In such a case the circuitry for the calling edge always propagates a received logical high signal and stores the identity of the corresponding returning edge.

For the returning edges, a return from an embedded network to the network within which it is embedded requires a check that the value indicative of that returning edge is stored in the associated memory (e.g. present at the top of the stack). Further, there is performed a check that the current input token output by the buffer will be consumed by (match the input-consumption condition of) one of the immediately subsequent input-consuming edges that is downstream of the returning edge in the RTN.

However, in certain situations the check that the current input token provided by the buffer will be consumed by one of the immediately subsequent input-consuming edges can be omitted, and an incoming logical high signal is propagated by the circuitry for the returning edge only dependent on the check of the memory contents (e.g. value on top of the stack).

This check of the input token being consumed is not required in the case where there is no alternative transition to the returning edge that could progress the parse, except for other returning edges. Specifically, the check of the input token is not required if there are no other edges competing with a returning edge in the RTN to continue the parse, except for other returning edges. In other words, there are no other edges sharing the same source vertex as the returning edge (and therefore no other edges branching off from the same source vertex as the returning edge), except for any other returning edges. In such a case, the stack popping operation occurs without any input token check, and the circuitry for the returning edge propagates a received logical high signal dependent only on the check that the value indicative of that returning edge is present at the top of the stack.

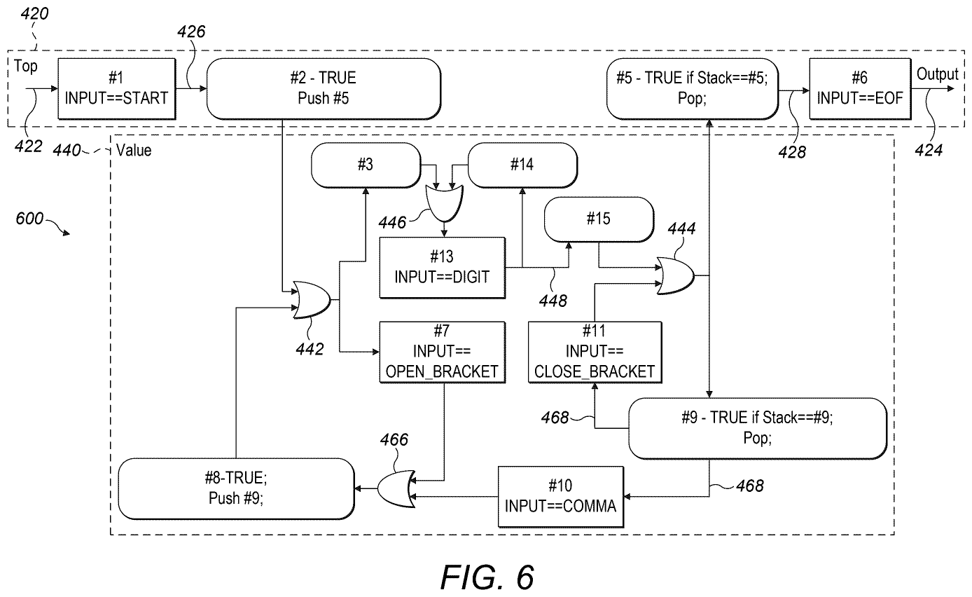

FIG. 6 shows a schematic logical diagram of a digital electronic circuit 600 according to the hardware description generated from the RTN 400 of FIG. 4 with the above-described optimisations being applied. As can be seen in FIG. 6, the circuitry for calling edges 2 and 8 does not include the checking of the current input token operation. This is because in the RTN 400 of FIG. 4, neither of calling edges 2 or 8 have competing edges, i.e. other edges sharing the same source vertex 426/466.

Further, as can be seen in FIG. 6, the circuitry for returning edges 5 and 9 does not include the checking of the current input token operation. This is because in the RTN 400 of FIG. 4, for returning edge 5 the only competing edge (i.e. edge also having source vertex 444) is returning edge 9, and vice versa. There is no non-returning edge with vertex 444 as a source vertex.

The reader will note that, although a competing edge is described as one sharing the same source vertex in the description above, two edges are also competing edges if the source vertex for one of the edges is connected to the source vertex for the other edge by a path that allows transition unconditionally (e.g. a path consisting only of epsilon transitions). This is because the implemented circuitry for both vertices would be logically high at the same time.

In general terms, the generated hardware description can either be entirely optimised as outlined above (with no input token checks on the calling and returning edges), or entirely non-optimised (with input token checks on every calling and returning edge). The degree to which optimisations may be made will depend on the specific grammar. In some embodiments, the generated hardware description includes both optimised and non-optimised calling and returning edges, where some of the calling and returning edges perform checks based on the current input token and some of the calling and returning edges do not perform such checks.

The preceding description so far has discussed transition networks for a grammar description that does not include any condition elements or action elements such as an RTN. However, the techniques described above may also be applied to transition networks representative of a grammar codified in a grammar description that includes: i) one or more condition elements, or ii) one or more action elements and one or more condition elements. An example of such a transition network is an augmented transition network (ATNs), which also may represent the rules of a grammar, and also may include input-consuming edges and non-input-consuming edges. The techniques described above may also be applied to any other ‘transition network’ that includes such features and may represent the rules of a grammar.

### Hardware Implementation of ATN

Some data formats, such as JSON schemas or XSDs, can be represented using LL(1) grammars. The example JSON schema shown below (SCHEMA 1) can be represented as an LL(1) grammar:

SCHEMA 1

```
{
  “type” : “array”,
  “items” : {
    “type” : “number”
  }
}
```

For data formats that can be represented by LL(1) grammars, the grammar can be represented using RTNs, which may be implemented in hardware using the methods and techniques described above.

However, for some data formats that can be represented as an LL(1) grammar, the implementation of the RTN for that grammar in hardware can be impractical, even though it is possible. The example JSON schema shown below (SCHEMA 2) would require an LL(1) grammar to consider all possible orders of the fields (“age”, “height”, and “weight”) occurring once each, which would become challenging from a hardware implementation perspective when scaled up to larger numbers of fields. This is because the number of production rules in the grammar would scale factorially with the number of fields:

SCHEMA 2

```
{
  “type” : “object” ,
  “properties” : {
    “age” : {
      “type″ : “number”,
    },
    “height” : {
      “type″ : “number”,
    },
    “weight” : {
      “type″ : “number”,
    },
  },
  “required” : [“age”, “height”, “weight”]
  }
}
```

Therefore it is not practical to represent the JSON schema of SCHEMA 2 with an LL(1) grammar and implement the RTN for that LL(1) grammar in hardware. Further, some data formats cannot be represented as an LL(1) grammar at all.

For data formats that cannot, or cannot practically, be represented by LL(1) grammars, techniques are described in the following sections that employ conditions or both actions and conditions in transition networks, such as in augmented transition networks (ATNs), to provide a hardware description for a hardware implementation of a parser in the form of a digital electronic circuit to parse input data against the grammar of the data format. For example, where an LL(1) grammar for a data format is impractical to implement in hardware, such as shown in SCHEMA 2 above, the same data format can be represented using different grammar description that includes action and/or condition elements (discussed in more detail below). The grammar description that includes action and/or condition elements may be in the ANTLR G4 notation, or any equally expressive grammar notation. An ATN can then be generated based on the grammar description that includes action and/or condition elements, and techniques are described herein for implementing this ATN within a digital electronic circuit.

One example use case for action and/or condition elements in a grammar description is to remove an ambiguity. In essence, this provides a ‘parsing hint’ to the parser to remove incorrect choices when an interpretation is ambiguous. The section below titled ‘Hardware Implementation for Locally Defined Variables’ illustrates such a use case.

Another example use case for action and/or condition elements in a grammar description is to add additional constraints to reflect requirements of the data format. The section below titled ‘Hardware Implementation for Rule Attributes’ illustrates such a use case.

A grammar description may include action/condition elements for both of these use cases in combination, or neither of them; in other words, the techniques of this disclosure are not limited to these particular use cases and other possibilities will be apparent to the skilled reader.

### Hardware Implementation for Locally Defined Variables

With reference to SCHEMA 2 above, rather than representing the schema using an LL(1) grammar that anticipates every permutation of the sequence of “age”, “height”, and “weight” fields in which each of “age”, “height”, and “weight” appears once, a new grammar can be introduced, where the new grammar allows each of “age”, “height”, and “weight” to appear any number of times. This new grammar can be referred to as a “relaxed grammar” because the constraints on number of appearances of “age”, “height” and “weight” are relaxed. A grammar description for this relaxed grammar is shown below using ANTLR G4 syntax:

ANTLR G4 SPECIFICATION 1

```
content:
  START_OBJECT
  ( WEIGHT COLON NUMBER
  | HEIGHT COLON NUMBER
  | AGE COLON NUMBER )
  ( COMMA
  ( WEIGHT COLON NUMBER
  | HEIGHT COLUMN NUMBER
  | AGE COLON NUMBER ) ) *
  END_OBJECT
  ;
```

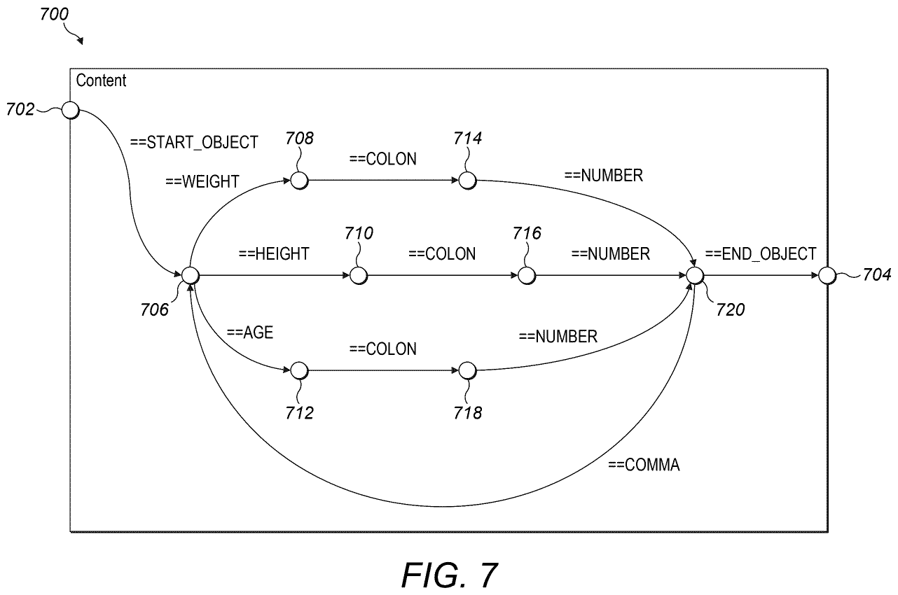

The grammar of ANTLR G4 SPECIFICATION 1 can be straightforwardly represented in an RTN, as shown in FIG. 7. The RTN 700 of FIG. 7 includes a start vertex 702 and an end vertex 704. The start vertex 702 is connected to an intermediate vertex 706 via an input-consuming edge with the input-consumption condition “==START_OBJECT”. The intermediate vertex 706 is the source vertex for three input-consuming edges, which have input-consumption conditions “==WEIGHT”, “==HEIGHT”, and “==AGE” respectively, and are connected to intermediate vertexes 708, 710, and 712 respectively. Each of intermediate vertices 708, 710, and 712 are connected via a respective input-consuming edge with the input-consumption condition “==COLON” to intermediate vertices 714, 716, and 718 respectively. Each of intermediate vertices 714, 716, and 718 are connected to intermediate vertex 720 via a respective input-consuming edge with the input-consumption condition “==NUMBER”, such that intermediate vertex 720 is the destination vertex for each of the three input-consuming edges with the input-consumption condition “==NUMBER”. The intermediate vertex 720 is connected to the intermediate vertex 706 by an input-consuming edge with the input-consumption condition “==COMMA”. Further, the intermediate vertex 720 is connected to the end vertex 704 by an input-consuming edge with the input-consumption condition “==END_OBJECT”.

The RTN 700 that represents the relaxed grammar of ANTLR G4 SPECIFICATION 1 could be practically implemented in hardware, for example using the methods described above in the section titled ‘Hardware Implementation of RTN with Embedded Networks’, with or without embedded networks. Further, it would remain practical to represent such relaxed grammars with RTNs and implement these in hardware, even if the number of fields were greatly increased. This is because accounting for each field being identified exactly once in any order increases in a factorial manner based on the number of fields. However, the relaxed grammar of ANTLR G4 SPECIFICATION 1 does not represent SCHEMA 2. Thus, while more readily implementable, it does not solve the problem of implementing a parser for SCHEMA 2.

But, by providing a further modification, SCHEMA 2 can be represented using the following grammar description, using ANTLR G4 syntax as before):

ANTLR G4 SPECIFICATION 2

```
content:
  locals [int nWeight=0; int nHeight=0; int nAge=0; ]
  START_OBJECT
  ( WEIGHT COLON NUMBER {$nWeight+=1;}
  | HEIGHT COLON NUMBER {$nHeight+=1;}
  | AGE COLON NUMBER {$nAge+=1;} )
  ( COMMA
  ( WEIGHT COLON NUMBER {$nWeight+=1;}
  | HEIGHT COLUMN NUMBER {$nHeight+=1;}
  | AGE COLON NUMBER {$nAge+=1;} ) ) *
  END_OBJECT {$nAge==1 && $nWeight==1 && $nHeight==1}?
;
```

For simplicity, the lexing rules for START_OBJECT, NUMBER, WEIGHT, etc. are not included in ANTLR G4 SPECIFICATION 1 or ANTLR G4 SPECIFICATION 2.

ANTLR G4 SPECIFICATION 2 represents a context-free grammar that additionally includes rules defined by actions and conditions. In particular, ANTLR G4 SPECIFICATION 2 is the same as ANTLR G4 SPECIFICATION 1, except that it includes the following action elements: [int nWeight=0; int nHeight=0; int nAge=0;], {$nWeight+=1;} {$nHeight+=1;}, {$nAge+=1;}. These action elements are written in computer code using the Java programming language in this example, although the techniques of this disclosure are not so limited.

The action element [int nWeight=0;] creates a counter for counting instances of “weight”, the counter starting with the value 0. Put another way, the action element [int nWeight=0;] initialises a locally defined variable ‘nWeight’ to 0.

The local variable (or ‘locally defined variable’) is initialised for the specific rule of the grammar (‘content’ in this case) each time that rule is encountered during parsing.

The action element {$nWeight+=1;} then increments the weight variable counter by 1, i.e. increases the value stored in the local variable ‘nWeight’ by 1 when a “weight” input is encountered during parsing. The action elements for “height” and “age” function analogously, incrementing respective local variables ‘nHeight’ and ‘nAge’ when encountering “height” or “age” during parsing.

ANTLR G4 SPECIFICATION 2 also further includes the condition element {$nAge==1 && $nWeight==1 && $nHeight==1}?. This condition element provides a Boolean output of ‘1’ or ‘TRUE’ if each of the Weight, Height and Age counters is equal to 1 and ‘0’ or ‘FALSE’.

The grammar described by ANTLR G4 SPECIFICATION 2 counts how many instances of each of the input tokens WEIGHT, HEIGHT, and NAME occur in a given input data sequence, and requires (through the condition element) that any input data to satisfy the rule “content” must include each of the WEIGHT, HEIGHT, and NAME input tokens only once. Put another way, the action and condition elements excludes the alternatives allowed by the relaxed grammar but not by the original grammar to only allow WEIGHT, HEIGHT, and NAME appearing once each within the scope of the rule represented by the action and condition elements. The grammar described by ANTLR G4 SPECIFICATION 2 represents SCHEMA 2. Advantageously, a transition network (such as an ATN) generated based on ANTLR G4 SPECIFICATION 2 may be more practically implemented in hardware than one that does not feature the relaxing of the grammar and introduction of the action elements and condition elements.

As described in the example above, an action element in a grammar description can be used to count instances of input tokens and a condition element can check that the count matches a condition, and reject input data as non-conforming to the grammar (failing to successfully parse) if the condition is not met. More generally, an action element stores one or more values in memory and a condition element provides a Boolean output based on a value stored in memory.

Although the Java programming language has been used in the present embodiment for the computer code of the action and condition elements, in general any other suitable programming language may be used for the action and condition elements. The purpose is to describe the particular operations to be performed in a definite and unambiguous manner. The techniques of this disclosure are therefore not limited to examples in which the computer code is in the Java programming language.

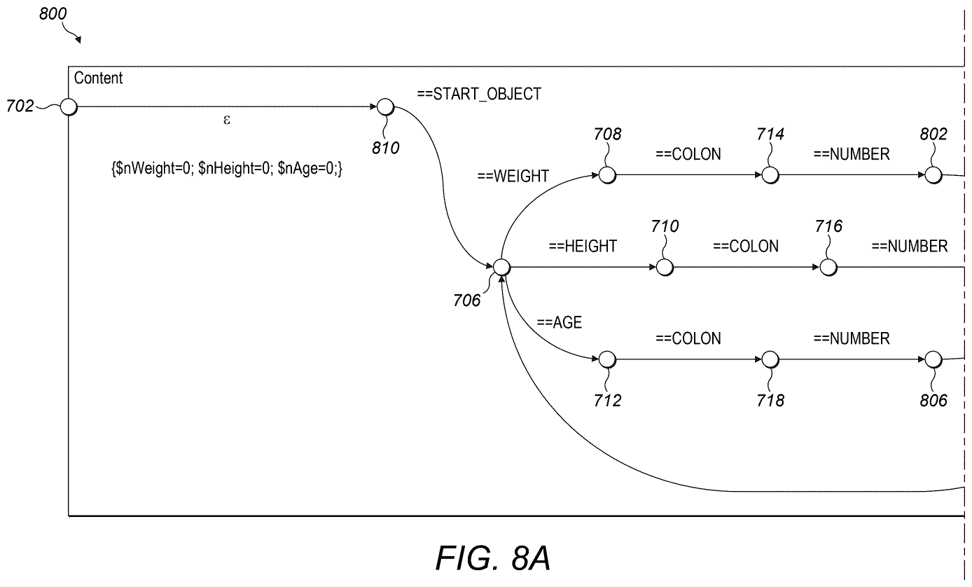

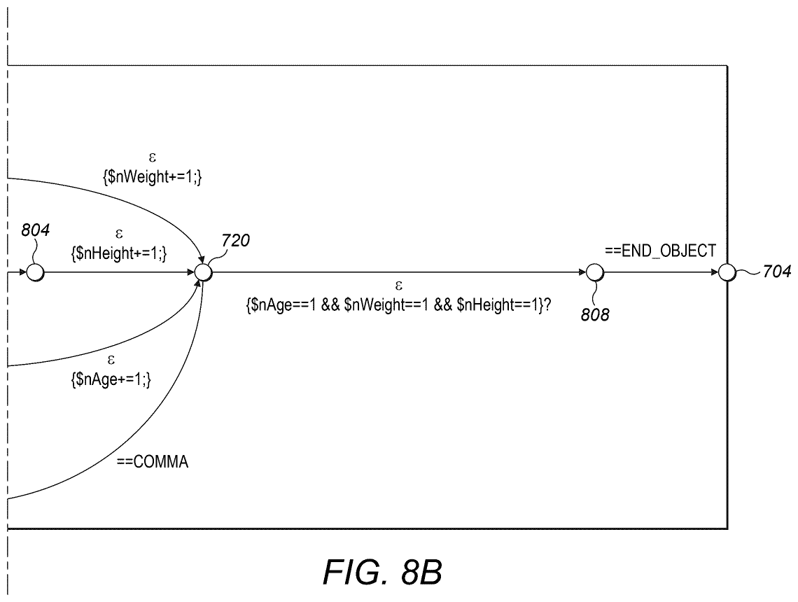

An Augmented Transition Network (ATN) may be generated for a grammar description that includes action and condition elements according to established techniques in this technical field. FIG. 8 shows an ATN representation 800 for the grammar description of ANTLR G4 SPECIFICATION 2. The ATN 800 is the same as the RTN 700 of FIG. 7, except that each input-consuming edge with the input-consumption condition “==NUMBER” is not connected to intermediate vertex 720, but is instead connected to a respective intermediate vertex 802, 804, and 806. Each of intermediate vertices 802, 804, and 806 are connected to intermediate vertex 720 via a respective action edge.

An action edge is a non-input-consuming edge, i.e. an epsilon transition, that is associated with the computer code of the corresponding action element from the grammar description. In the present embodiment, the action element {$nWeight+=1;} is associated with the action edge between intermediate vertex 802 and intermediate vertex 720, the action element {$nHeight+=1;} is associated with the action edge between intermediate vertex 804 and intermediate vertex 720, and the action element {$nAge+=1} is associated with the action edge between intermediate vertex 806 and intermediate vertex 720.

Further, in the ATN 800 of FIG. 8, the intermediate vertex 720 is not the source vertex for the input-consuming edge with the input-consumption condition “==END_OBJECT”, but rather is the source vertex for a condition edge connecting the intermediate vertex 720 with an intermediate vertex 808.

A condition edge is a non-input-consuming edge, i.e. an epsilon transition, that is associated with the computer code of the corresponding condition element from the grammar description. In the present embodiment, the condition element {$nAge==1 && $nWeight==1 && $nHeight==1}? is associated with the condition edge between intermediate vertex 720 and intermediate vertex 808. The intermediate vertex 808 is then connected to the end vertex 704 by the input-consuming edge with the input-consumption condition “==END_OBJECT”.

Further, in the ATN of FIG. 8, the start vertex 702 is not the source vertex for the input-consuming edge with the input-consumption condition “==START_OBJECT”, but rather is the source vertex for an action edge connecting to an intermediate vertex 810. This action edge has associated with it the action defined by {$nWeight=0; $nHeight=0; $nAge=0;} (corresponding to action element [int nWeight=0; int nHeight=0; int nAge=0;] in ANTLR G4 SPECIFICATION 2), which initialises the local variables nWeight, nHeight, and nAge to zero. The intermediate vertex 810 is the source vertex for the input-consuming edge with the input-consumption condition “==START_OBJECT”.

As can be seen from FIG. 8, one approach to generating an ATN is to first generate the RTN for a version of the grammar description that has all action and condition elements removed. For the present embodiment, this would be the RTN shown in FIG. 7 for ANTLR G4 SPECIFICATION 1. Then, in order to generate the ATN including action and condition edges for the action and condition elements, the RTN is extended to include new vertices and epsilon transitions at the appropriate locations for the action and condition elements in the grammar description, with the newly added epsilon transitions tagged with or associated with the computer code for the relevant action element or condition element. An alternative approach is to generate the ATN directly from the grammar description, without generating the RTN as an intermediate step, with action and condition elements of the grammar represented in the ATN by non-input-consuming edges that include (are tagged with or associated with) the computer code of the associated action or condition element.

Once an ATN has been generated for a grammar description including action and condition elements, the ATN can be digitally stored, and then a hardware description for configuring a digital electronic circuit can be generated based on the ATN, to implement the ATN in hardware. Implementing the ATN in hardware produces a digital electronic circuit able to parse input data against the grammar of the data format defined in the grammar description including action and condition elements, i.e. ANTLR G4 SPECIFICATION 2 in the present embodiment. The hardware description can be generated using the same methods as described above in FIGS. 1 to 6 for RTNs, which will not be repeated here, in combination with the methods described below to enable the action and condition elements for the relevant action and condition edges in the ATN to be implemented in the hardware description. It is noted that in some embodiments the ATN may include embedded networks similar to those discussed previously in the Hardware Implementation of RTN with Embedded Networks section, which can be implemented in hardware using the same techniques as described in that section.

In general, the techniques of this disclosure are not limited to a particular method of generating an ATN. The independent claims recite providing a digitally stored graph representing a transition network based on the rules of a grammar, wherein the grammar is codified in a grammar description that includes i) one or more condition elements or ii) one or more action elements and one or more condition elements. Such a transition network may be an ATN. Providing such a digitally stored graph representing the transition network may comprise generating the graph, generating a portion of the graph, or may comprise retrieving the graph from digital storage for example. The independent claims define how that transition network is used as a starting point to generate a hardware description for configuring a digital electronic circuit by implementing circuitry in the hardware description in accordance with the transition network. The techniques of this disclosure more generally are not limited to any particular method of providing (e.g. generating) such a transition network.

To generate a hardware description from the digitally stored ATN, the hardware description includes instructions for implementing circuitry for each of the action and condition edges in the ATN that performs the functionality of the respective action or condition elements associated with that action or condition edge, i.e. the functionality defined by the computer code. In the present embodiment, the functionality is defined by the Java syntax of the action and condition elements. In embodiments involving locally defined variables, all action and condition elements can be considered to be or interpreted as functions operating on the locally defined variables as the parameters. In the case of action elements, the functions store a value for that local variable. In the case of condition elements, the functions return a Boolean value based on the locally defined variable. Thus, the action {$nWeight+=1;} can be considered equivalent to or synonymous with the function ‘incrementByOne (nWeight)’, which performs the incrementing operation.

Further, the condition {$nAge==1 && $nWeight==1 && $nHeight==1}? can be considered equivalent to or synonymous with the function areAllEqualToOne (nAge,nWeight,nHeight), which provides the corresponding output if all of the input parameters are equal to one.

The hardware description may then be generated based on a mapping between these functions and equivalent circuitry to provide this functionality, as will be discussed further with an example below.

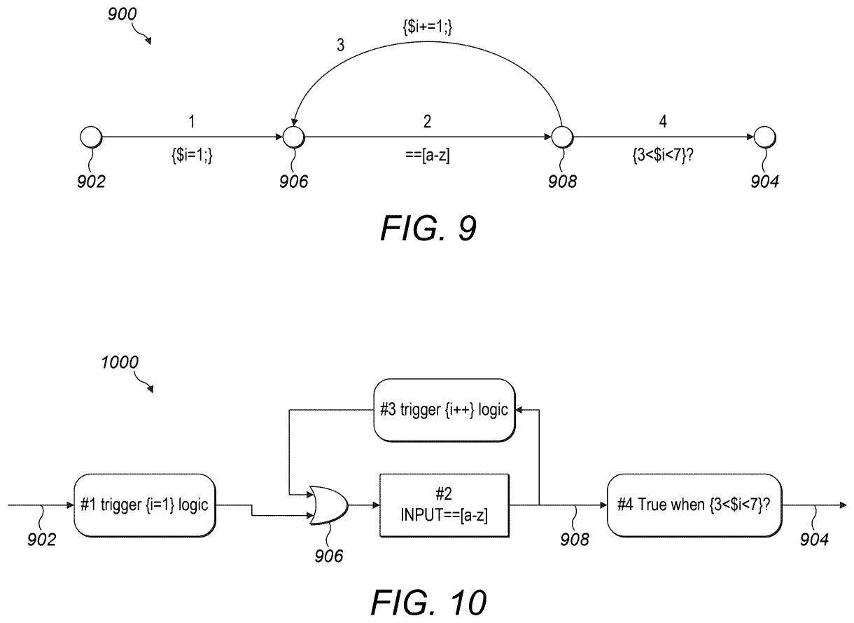

In order to explain the generation of the hardware description for action and condition edges, a simple grammar description and corresponding ATN will now be considered, with reference to FIGS. 9 to 11.

ANTLR G4 SPECIFICATION 3 below shows a grammar description using ANTLR G4 syntax that can occur where length-checking of strings is required in parsing according to a grammar that defines a data format.

ANTLR G4 SPECIFICATION 3

locals [int i=0;]:
([a-z]{$i+=1;})+ {3<$i<7}?

The grammar description of ANTLR G4 SPECIFICATION 3 can be represented by the ATN 900 shown in FIG. 9. The derivation of the ATN 900 from the grammar description of ANTLR G4 SPECIFICATION 3, including why the local variable “i” is initialised to a value of 1 in the ATN 900, will be apparent to the reader based on the discussion in the section below titled ‘Optimisations of ATN Implementations’.

The ATN 900 of FIG. 9 includes a start vertex 902 and an end vertex 904. The start vertex 902 is the source vertex for an action edge 1 associated with the action element {$i=1;} that initialises the local variable “i” with an initial value of 1, and has intermediate vertex 906 as destination vertex of this action edge 1. Intermediate vertex 906 is connected to an intermediate vertex 908 by an input-consuming edge 2 with the input-consumption condition “==[a-z]”. The intermediate vertex 908 is connected to intermediate vertex 906 via an action edge 3 associated with the action element {$i+=1;} from the grammar description, which increments the value of “i” by one. The intermediate vertex 908 is also connected to the end vertex 904 via a condition edge 4 associated with the condition element {3<$i<7}? from the grammar description, which checks if the value of “i” is greater than 3 and less than 7.

In ANTLR G4 SPECIFICATION 3 and ATN 900, the regular expression “[a-z]” means that the input-consuming edge allows a transition from its source vertex to its end vertex if the input (e.g. current input token) is any letter of the alphabet. In ANTLR G4 SPECIFICATION 3 and ATN 900, the counter of local variable “i” counts the number of letters, and the condition only allows a successful parse if the number of letters in the input data sequence is 4, 5 or 6.

Generating the hardware description includes implementing, in the hardware description, circuitry for each action edge in the ATN. The implemented circuitry for each action edge performs an operation, i.e. the functionality, in accordance with the computer code of the associated action element. The operation for each action element involves storing a value in memory. In the present embodiment, the value stored in memory is the value of the locally defined variable “i”, with the circuitry for action edge 1 setting i equal to 1, and the circuitry for action edge 3 increasing the value stored for “i” by one.

Generating the hardware description further includes implementing circuitry, in the hardware description, for each condition edge in the ATN. The implemented circuitry for each condition edge evaluates the function defined in the computer code of the associated condition element based on the value stored in memory by the circuitry of the corresponding action edge or edges. The implemented circuitry for each condition edge selectively permits propagation of a logical high through the implemented circuitry, based on the output of the function. In the present embodiment, the implemented circuitry for condition edge 4 compares the stored value of “i” to the inequality 3<i<7, and therefore only allows propagation of a logical high signal if the local variable “i” is within this range.

The implemented circuitry for a condition edge is generally located in the digital electronic circuit downstream of the circuitry for the corresponding action edges, i.e. the action edges that operate on the same locally defined variable that is used during the evaluation of the function of the condition element. This ensures that condition edges use the correct stored values of the locally defined variables to provide the correct condition-checking functionality.

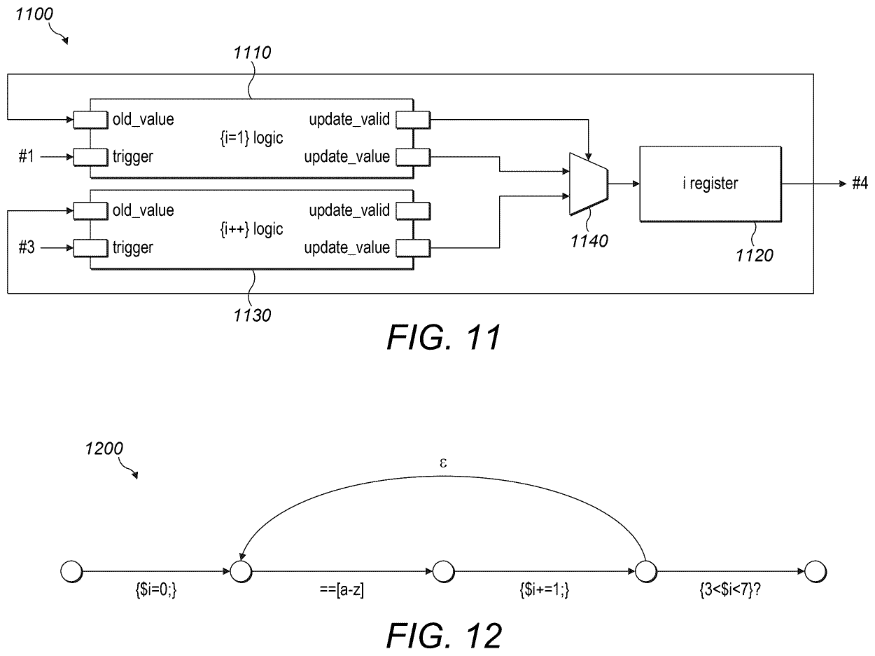

FIGS. 10 and 11 show schematic logical diagrams of a digital electronic circuit created according to the hardware description generated based on ATN 900 in accordance with the methods described herein. FIG. 10 shows a first portion 1000 of the digital electronic circuit and FIG. 11 shows a second portion 1100 of the digital electronic circuit.

The first portion 1000 is generated from the ATN 900 in a manner analogous to the methods described herein in relation to FIGS. 1 to 6 (with no calling or returning edges and corresponding circuitry being present in this embodiment), with the addition of the logic that is included in the circuitry for the action and condition edges. Specifically, the portion 1000 of the digital electronic circuit of FIG. 10 includes circuitry for the start vertex 902 coupled to circuitry for action edge 1. The portion 1000 includes an OR gate in the circuitry for vertex 906, with the circuitry for action edges 1 and 3 coupled to the input terminals of the OR gate. The output of the OR gate in the circuitry for vertex 906 is coupled to circuitry for the input-consuming edge 2. The circuitry for the input-consuming edge 2 is coupled via the circuitry of vertex 908 to both circuitry for the condition edge 4 and circuitry for action edge 3.

The circuitry for action edge 1 includes combinational logic that, on receipt of a logical high signal from the circuitry for vertex 902, propagates a logical high signal to the trigger terminal marked #1 in the portion 1100 of the digital electronic circuit shown in FIG. 11, and also propagates a logical high signal to the circuitry for vertex 906. Similarly, the circuitry for action edge 3 includes combinational logic that, on receipt of a logical high signal from the circuitry for vertex 908, propagates a logical high signal to the trigger terminal marked #3 in the portion 1100 of the digital electronic circuit shown in FIG. 11, and also propagates a logical high signal to the circuitry for vertex 906.

As shown in FIG. 11, the circuitry for action edge 1 includes a logic circuit 1110 that, on receipt a logical high signal at the trigger terminal marked #1, initialises the local variable “i”, by storing (via mux logic 1140) a value of 1 in register 1120 for the local variable “i”.

Similarly, the circuitry for action edge 3 includes a logic circuit 1130 that, on receipt a logical high signal at the trigger terminal marked #3, reads the value stored in the local variable register 1120, and stores (via mux logic 1140) an adjusted value in the register 1120 equal to the previous value of “i” stored in the register increased by one.

In the present embodiment, the logic circuits 1110 and 1130 follow the following standard interfacing pattern.

The interfacing inputs are
1) A trigger signal: wired up to the appropriate location in the digital electronic circuit for the action edge in the ATN.
2) The old local variable value: wired to the output of the register that stores the local variable value.
3) Supplementary input arguments (as appropriate): wired up to registers containing other values necessary to complete the variable update (discussed later). The supplementary input arguments may be relevant for more complex actions than those of the present embodiment, e.g. where the value written to the variable depends on other stored values or on the value of a current or previous input token.

The interfacing outputs are:
1) The updated local variable value: wired up to the variable register input (via mux (multiplexer) logic so that the circuitry for multiple action edges can update the local value register).
2) Valid Flag: used for controlling the variable update mux and register-enable logic.
3) Error flag: used to update an error flag register that accompanies the variable register.

The corresponding error register, the update-enable logic, and the full details of the mux selection circuit, taking account of both update_valid signals, are omitted from FIG. 11, for the sake of clarity.

The skilled reader will appreciate that the implementations of action edges 1 and 3 are not limited to the example shown in FIG. 11 and that updating of the appropriate local variables in registers or other memory storage in accordance with action edges 1 and 3 may be achieved in many other ways in accordance with digital circuit design techniques that will be familiar to the skilled reader.

An advantage of using a standard interfacing framework, such as that described above, is that circuitry implementations for multiple action edges can be instantiated/auto-coded to update the same local variable in a consistent manner.

A standard interfacing framework also provides an advantage in that individual action edge implementations can be statically coded to build up a library of static action implementations, with the appropriate implementation selected from the library and instantiated as required in accordance with the grammar description. Alternatively, these action edge implementations may be auto-coded instead, provided by a mixture of instantiating and auto-coding. For example, an exemplary implementation of the {i++} accumulate action (i.e. logic circuit 1130) in HDL is shown below:

EXAMPLE HDL IMPLEMENTATION OF ACCUMULATE ACTION

```
library ieee;
use ieee.std_logic_1164.all;
use ieee.numeric_std.all;
-- illustration of how an accumulate action could be implemented in VHDL
entity accumulate_action is
  generic(
    BIT_WIDTH : natural
  );
  port(
    clk : in std_logic; --clock unused in this example
    trigger : in std_logic;
    old_value : in unsigned(BIT_WIDTH-1 downto 0) := (others => ‘0’);
    update_valid : out std_logic;
    update_value : out unsigned(BIT_WIDTH-1 downto 0) := (others => ‘0’);
    update_error : out std_logic
  );
end accumulate_action;
architecture rtl of accumulate_action is
  constant OVERFLOW_VALUE : unsigned(BIT_WIDTH-1 downto 0) := (others => ‘1’);
begin
  --update logic: purely combinational for this action
  update_valid <= trigger;
  update_error <= ‘1’ when old_value = OVERFLOW_VALUE else ‘0’;
  update_value <= old_value + 1;
end;
```

In the portion 1000 of the digital electronic circuit shown in FIG. 10, the circuitry for condition edge 4 includes combinational logic that, on receipt of a logical high signal from the circuitry for vertex 908, checks the value of “i” stored in the local variable register 1120 against the condition of the associated condition element, i.e. it evaluates the function defined in the computer code of the associated condition element, and provides a logical high to the circuitry to circuitry for vertex 904 only if the condition is met. In this way, the circuitry for the condition edge 4 allows propagation of a logical high signal through the digital electronic circuit. Therefore the circuitry for the condition edge 4 only allows a successful parse to occur if the condition of the associated condition element is satisfied at the point of evaluation. This has the effect that only input data that conforms to the grammar description that includes the action and condition elements (ANTLR G4 SPECIFICATION 3 in the present embodiment) will result in a successful parse by the digital electronic circuit configured according to the hardware description.

Analogously to the example shown for FIGS. 9 to 11, the ATN of the embodiment of FIGS. 7 and 8 can be implemented in a digital electronic circuit. In such a circuit, each of the local variables nAge, nWeight, and nHeight are be initialised to an initialisation value and the values stored in the variables adjusted by the circuitry for the action edges. The circuitry for the condition edge would check that each of the stored values for nAge, nWeight, and nHeight are equal to one. In this way, such a circuit performs a counting check on the input tokens AGE, WEIGHT, and HEIGHT. In particular, the counting check enforces the requirement that, in the portion of the input data between the input tokens START_OBJECT and END_OBJECT, each of the input tokens AGE, WEIGHT, and HEIGHT appears exactly once in order for the data to be parsed successfully.

Condition elements are not limited to these particular examples but may be any Boolean output function of stored data in accordance with the requirements of the grammar of the data format. Other counting-based checks may require each input token to appear a number of types other than one. The required number of times might be static, i.e. defined explicitly in the grammar description. The required number of times might be dynamic, e.g. defined during the parsing process based on previously parsed data, whether based directly on the values of input tokens or based on actions performed previously, such as the result of a previous counting sequence performed on previous input tokens. In the case of numerical ranges, the range might be a static range defined in the grammar description, such as the 3<i<7 inequality for local variable “i” in the embodiment of FIGS. 9 to 11, or the range might be dynamically defined during the parsing process.

The techniques of this disclosure are not limited to the use of action elements for counting purposes. An action element might define any electronically implementable operation that involves the storing of data, such as performing multiplication, or division operations on values, or evaluating a non-linear function of a value or group of values, such as evaluating a power of a value, an exponential function of a value, a logarithm of a value, a trigonometric function of a value or its inverse, or the like. In addition, the value stored by an action element is not required to be a numerical value, integer or non-integer, but may be a Boolean value or an alphanumeric character (representable numerically), or may be a group of characters in the form of a string, or may potentially be in the form of a more complicated data structure such as a record (struct) or any compound data structure.

The condition elements may also comprise computer code for performing more complex operations on stored values, such as performing multiplication, or division operations on values, or evaluating a non-linear function of a value or group of values, such as evaluating a power of a value, an exponential function of a value, a logarithm of a value, a trigonometric function of a value or its inverse, or the like. An example of a condition element comprising computer code for a trigonometric function is set out below. A condition element may also comprise computer code for performing operations on stored values that represent non-numeric data, such as characters or strings or represent more complicated data structures such as a record (struct), or any compound data structure.

As an illustrative example to relate more general operations than counting to examples discussed previously with regard to FIGS. 7 and 8, some grammars might require storing the actual numerical values of the input tokens AGE, WEIGHT, and HEIGHT as the locally defined variable by the circuitry for the action edges. The circuitry for the condition edge could then check that the numerical values for these locally stored variables all fall within particular ranges, if required to do so by the grammar.

As discussed above, locally defined variables in a grammar description require initialisation. The hardware description provides registers or other memory locations to allow the local variables to persist over time. It is these registers or other memory locations that require suitable initialisation. If a circuitry for a rule for a grammar is entered during a parse multiple times, it may be necessary to initialise (reinitialise) these local variables in the memory each time if it is required that the check of the condition element is to apply only to that instance, i.e. the domain of application of the check performed by the condition element is limited to that particular set of inputs.

For example, referring back to ANTLR G4 SPECIFICATION 2 and the ATN 800 of FIG. 8, the ATN 800 could be an embedded network appearing at multiple locations within a larger transition network (similar to the embedded networks discussed in the section titled ‘Hardware Implementation of RTN with Embedded Networks’ above). Each time the rule “content” of ATN 800 (i.e. an embedded version of ATN 800) is entered during parsing against the grammar, the local variables nWeight, nHeight, and nAge must be reinitialised, i.e. a new set of relevant local variables are created for that rule each time the rule is entered. Put another way, the implemented circuitry for ATN 800 could be re-used at multiple locations within a larger digital electronic circuit, e.g. by multiple calling edges in the larger digital electronic circuit calling the implemented circuitry for ATN 800. Each time a new call is made to the implemented circuitry for ATN 800, the local variables nWeight, nHeight, and nAge must be reinitialised.

Once a rule such as the “content” rule of ATN 800 has been entered (or its domain of application has been entered), the local variables must be initialised before any other actions occur. This initialisation is expressed in the ATN via appropriate initialisation action edges, as discussed above, and these initialisation action edges are preferably at, or close to, the start of the ATN for that rule to ensure that actions that manipulate (adjust) existing stored data do not act on undefined data in a non-initialised variable. The initialisation action edge does not have to be at the very start of the ATN (i.e. need not be the first directed edge of the ATN) provided that: the initialisation action edge is traversed before any subsequent action edges in the ATN involving the same local variable; and the initialisation action edge is positioned within the ATN such it can only be traversed once per rule entry.

Some grammars with action elements are recursive, where a rule (in the form of an embedded network) can be entered again before it has been exited, either due to direct or indirect recursion. In the hardware implementation for such grammars, any local variables associated with that rule (i.e. stored in registers or memory locations in the hardware implementation) can be stored in a local variable stack, such that a set of locally defined variables is stored for each level of the recursion.

Put another way, if an ATN for a given rule is embedded in itself or another ATN, each time a call is made to the embedded network (i.e. a call from a first level of recursion to a second level of recursion) the relevant value indicative of the corresponding returning edge for that calling edge is pushed to a stack as described for the embedded RTN techniques described previously. When this call is made, the local variables stored for the ATN containing the calling edge (i.e. the first level of recursion) can simultaneously be pushed to a local variable stack. Upon return from the embedded network (i.e. from the second level of recursion), when the relevant value indicative of that returning edge is popped for the stack according to the embedded network techniques, the relevant stored local variables can also be retrieved from the local variable stack, for example by a popping operation.

In this way, for grammars that require a condition to be satisfied at each level of recursion, such as a counting check of the number of certain input tokens in the relevant portion of input data for that level of the recursion, the hardware implementation can utilise the local variable stack to ensure that the condition is satisfied at all levels of the recursion.

In some embodiments, a dedicated stack is used as the local variable stack. In some embodiments, a combined stack for storing both the local variables and the value indicative of the corresponding returning edge during a call is used. Further, both local stacks or global stacks could be used for storing local variables, or the combination of one or more local stacks and a global stack for example.

In each of the above-described embodiments, each of the condition elements is a static condition, where the locally defined variable is compared to one or more predetermined comparison values. For example in the condition elements of the ATN 800 of FIG. 8, each of the local variables nWeight, nHeight, and nAge are compared to a predetermined comparison value of one. In the condition element of ATN 900 of FIG. 9, the local variable “i” is compared to a range defined by the predetermined comparison values three and seven. These predetermined comparison values are defined in the grammar description.

In some embodiments, dynamic condition elements are used, where a locally defined variable is compared to a dynamic comparison value. Such dynamic comparison values are not predetermined values defined by the grammar description, but are instead non-fixed values stored in memory, such as a current value of another locally defined variable, or some other value derived from the input tokens of the input data.

In some embodiments, a condition element requires that a pair of local variables satisfy a certain mathematical equation, such as requiring that the pair of locally defined variables both have the same value, e.g. {$nAge==$nWeight}?, or requiring that one local variable is larger than another, e.g. {$nHeight>$nWeight>$nAge}?. In this case, one local variable acts as the comparison value for another local variable. In such an embodiment, the implemented circuitry for the condition edge includes logic for retrieving the current value of each local variable from memory, and comparing these values.

In some embodiments the dynamic comparison value for a condition element is derived directly from one or more values of one or more input tokens. For example, for input data including an input token NUMBER, the numerical value of the NUMBER token may be stored in memory and used as a comparison value by the implemented circuitry for a condition edge.

### Optimisations of ATN Implementations

Returning to ANTLR G4 SPECIFICATION 3, an alternative ATN representation is shown in FIG. 12. The ATN 1200 of FIG. 12 maps directly onto ANTLR G4 SPECIFICATION 3, with action elements [int i=0;] and {$i+=1;} shown associated with corresponding action and condition edges in the ATN 1200 (where action element [int i=0;] corresponds to the action defined by {$i=0;} in the ATN 1200). However, a number of optimisations can be made to this ATN representation. These optimisations may advantageously improve performance in terms of logic utilisation in the implemented digital electronic circuit. These optimisations may advantageously increase throughput of the digital electronic circuit by reducing the number of necessary pipeline stalls.

For example, a pipeline stalling problem may occur when a condition edge occurs immediately following an action edge. Evaluation of the function of the condition edge requires that the operations defined by the action edge be completed first. The hardware implementation of the ATN 1200 might require a clock cycle without input consumption (and hence an input pipeline stall) in order for “i” to be updated before the condition {3<$i<7}? is tested. Moreover, some operations defined by an action edge or condition edge (such as the evaluation of a trigonometric function) might require multiple clock cycles to complete. A pipeline stall may arise if no account is taken of the time to complete these operations.

An ATN may be refactored to avoid or reduce pipeline stalls. A refactoring of an ATN may follow one or more (e.g. all) of the following ATN refactoring rules.

A first ATN refactoring rule is that the order of transitions can be interchanged where there is no branching.

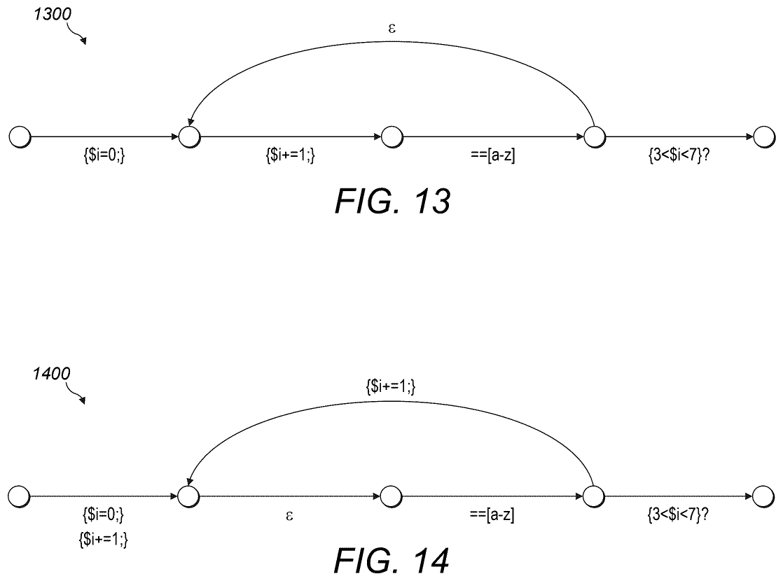

In the example ATN 1200 of FIG. 12, the transitions==[a-z] and {$i+=1;} always happen in strict succession. In this case, these transitions can be reversed, as shown in FIG. 13 with ATN 1300. This refactoring means that there is now no input pipeline stall required: the increment to “i” can take place in the same clock cycle as the input consumption “==[a-z]”.

However, in the ATN 1300 of FIG. 13 there is still a pipeline stall at the beginning of the input, because it is not possible to carry out two actions against the variable “i” in the same clock cycle (i.e. {$i=0;} and {$i+=1;}). To avoid this stall, a second refactoring can then be applied according to the following rule.

A second ATN refactoring rule is that actions can be pushed back in the ATN provided all branches are followed.

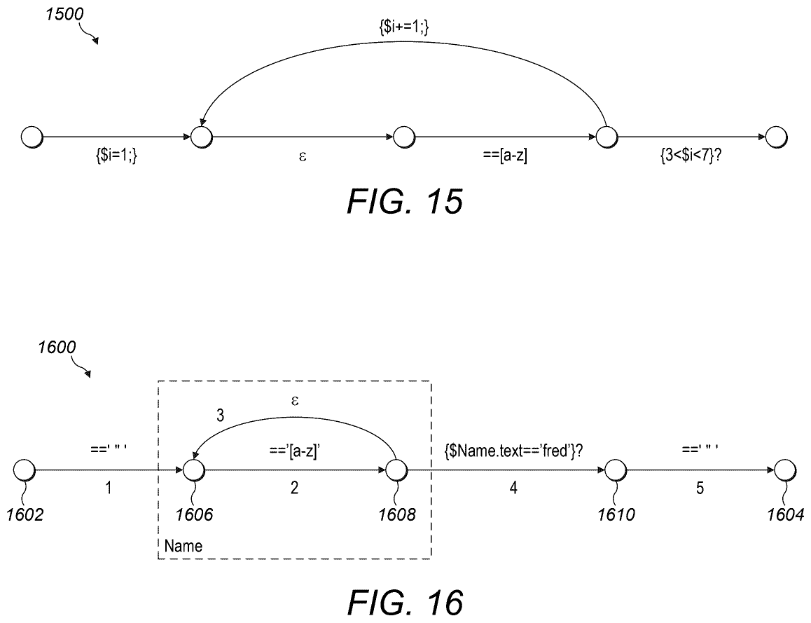

In the example ATN 1300 of FIG. 13, the action {$i+=1;} can be pushed backwards provided that both paths are followed. The result of this modification is shown in ATN 1400 of FIG. 14. Further, the two actions on variable “i” during the single (first) transition in the ATN 1400 of FIG. 14 may then be combined, resulting in the ATN 1500 of FIG. 15.

A third ATN refactoring rule is that two nodes joined by an E-transition can be combined.

Applying the third ATN refactoring rule results converts the ATN 1500 of FIG. 15 into the ATN 900 shown in FIG. 9 previously, and hence explains why ATN 900 can represent the grammar description of ANTLR G4 SPECIFICATION 3. In particular, this refactoring is the reason why ANTLR G4 SPECIFICATION 3 initialises the variable “i” with an initial value equal to zero, but the ATN 900 of FIG. 9 has an action edge initialising “i” with an initial value equal to one.

Following this refactoring, the ATN 900 of FIG. 9 can be implemented in hardware using the methods as outlined above, as discussed above in relation to FIGS. 10 and 11.

### Hardware Implementation for Rule Attributes

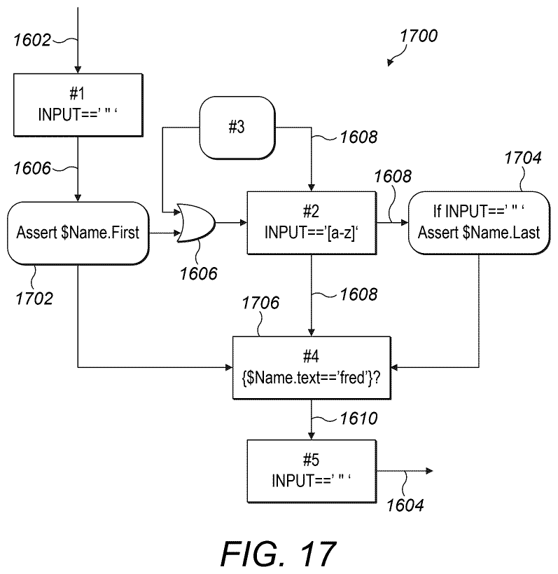

In addition to condition elements that perform checks on locally defined variables, e.g. to allow the counting checks described above, a further type of condition element that checks attributes for a particular rule of the grammar will now be discussed below in relation to FIGS. 16 and 17. Such condition elements can be used to add extra constraints to grammars, which can be used to make the grammar represent a specific data format such as a specific JSON schema.

A simple exemplary grammar is as follows:

ANTLR G4 SPECIFICATION 4

```
Top:
  ′“′ Name ′“′
  ;
Name:
  ′[a-z]′+
  ;
```

ANTLR G4 SPECIFICATION 4 describes a grammar having a rule “Name” that allows any input formed from any combination of the letters a to z, where each letter can appear any number of times.

A condition element can be added to ANTLR G4 SPECIFICATION 4 to further constrain the grammar of ANTLR G4 SPECIFICATION 4. For example, in a particular embodiment it could be desired that not only is the input data for the rule “Name” formed from some combination of the letters a to z, but also that the input data is a specific series of characters such as “fred”, which contains four input tokens in sequence: “f”, “r”, “e”, and “d”. A grammar description including such a condition element is shown below in ANTLR G4 SPECIFICATION 5:

ANTLR SPECIFICATION 5

```
Top:
  ′“′ Name {$Name.text==′fred′}? ′“′
  ;
Name:
  ′[a-z]′+
  ;
```

Specifically, ANTLR G4 SPECIFICATION 5 includes the condition element {$Name.text==‘fred’}?, discussed in more detail below.

An ATN 1600 for ANTLR G4 SPECIFICATION 5 is shown in FIG. 16. The ATN 1600 includes a start vertex 1602 and an end vertex 1604. The start vertex 1602 is the source vertex for an input-consuming edge 1 with the input-consumption condition “==” “The input-consuming edge 1 has intermediate vertex 1606 as its destination vertex. Intermediate vertex 1606 is connected to an intermediate vertex 1608 by an input-consuming edge 2 with the input-consumption condition “==‘[a-z]’”. The intermediate vertex 1608 is connected to intermediate vertex 1606 via an epsilon transition 3. The intermediate vertex 1608 is also connected to an intermediate vertex 1610 via a condition edge 4 associated with the condition element {$Name.text==‘fred’}? from the grammar description. The intermediate vertex 1610 is connected to the end vertex 1604 input-consuming edge 5 with the input-consumption condition “== ‘“’ ”.

As mentioned, the condition element {$Name.text==‘fred’} included in ANTLR G4 SPECIFICATION 5 and associated with the condition edge 4 in ATN 1600 performs a check that the input tokens parsed against the rule “Name” in the grammar are the input tokens “f”, “r”, “e”, and “d” in sequence. Thus the condition element of ANTLR G4 SPECIFICATION 5 performs additional checks on the input tokens beyond the grammar of ANTLR G4 SPECIFICATION 4, with only input data formed of input tokens: “, f, r, e, d,” resulting in a successful parse against the grammar of ANTLR G4 SPECIFICATION 5. To do this, the condition element takes as a parameter an attribute $Name.text of the grammar rule “Name”, and checks that this attribute matches the condition of being equal to a comparison value “fred”. In the present embodiment, the attribute $Name.text is the input token sequence parsed according to the rule “Name” in the native string form.

It should be noted, that while the term “attribute” is the terminology of the ANTLR software tool, the present invention is not limited to the ANTLR software tool in general. Within the context of the present invention, an attribute of a rule in the grammar (such as “Name”) is generally any representation of an input data sequence processed (parsed) previously by the rule of the grammar. Put another way, the condition element comprises computer code that defines a function that provides a Boolean output based on a comparison between a stored value derived from one or more input tokens (i.e. the attribute) and a comparison value (“fred” in the present embodiment).

This embodiment uses the ANTLR text attribute, to provide the corresponding input sequence for the rule “Name” in the native string form. This input sequence in the string form can then be compared to the comparison value “fred”. However, other attributes can be used to provide alternative representations of the input sequence. For example, the ANTLR ‘int’ attribute returns an integer representation of the input token sequence for that rule of the grammar. In general, any value derived from one or more input tokens parsed according to the rule of the grammar can be used as the attribute to be checked by the condition element.

This disclosure provides techniques for generating a hardware description for a digital electronic circuit to parse input data against grammars including such condition edges, e.g. ANTLR G4 SPECIFICATION 5, as will now be discussed. In particular, a hardware description for the ATN 1600 of FIG. 16 may be generated using a method analogous to those described above in the embodiments present previously, but with additional circuitry implemented by the hardware description for the condition edge that checks an attribute of a rule of the grammar.

FIG. 17 shows a schematic logical diagram of a digital electronic circuit created according to the hardware description generated based on ATN 1600 according to methods of the present disclosure.

The digital electronic circuit 1700 of Figure is generated from the ATN 1600 in an analogous manner to the methods described in relation to FIGS. 1 to 6 (with no calling or returning edges and corresponding circuitry being present in this embodiment), with the addition of logic that is included in the circuitry for the condition edge 4 of ATN 1600.

Specifically, the digital electronic circuit 1700 of FIG. 17 includes circuitry for the start vertex 1602 coupled to circuitry for input-consuming edge 1. Further, the circuit 1700 includes an OR gate in the circuitry for vertex 1606, with the circuitry for input-consuming edge 1 coupled to an input terminals of the OR gate (via a first section 1702 of circuitry for the condition edge 4). Further, circuitry for non-input-consuming edge 3 is coupled to the other input terminal of the OR gate in the circuitry for vertex 1606. The output of the OR gate in the circuitry for vertex 1606 is coupled to circuitry for the input-consuming edge 2. The circuitry for the input-consuming edge 2 is coupled via the circuitry of vertex 1608 to circuitry for the condition edge 4 (in particular a third section 1706 of the circuitry for the condition edge 4). The circuitry for the condition edge 4 is coupled via circuitry for vertex 1610 to circuitry for input-consuming edge 5. The circuitry for input-consuming edge 5 is coupled to circuitry for the end vertex 1604.

The circuitry for the condition edge 4 includes a first section 1702, a second section 1704 and a third section 1706.

The first section 1702 is coupled to the circuitry for the intermediate vertex 1606, such that the first section 1702 receives a logical high signal when the register in the circuitry for input-consuming edge 1 outputs a logical high (i.e. on the next clock tick after the input buffer outputs the input token ″). In the embodiment shown in FIG. 17, the first section 1702 is inserted part way through the coupling of the circuitry for the intermediate vertex 1606 such that, on receipt of a logical high signal from the circuitry for the intermediate vertex 1606, the first section 1702 outputs a logical high signal to an input terminal of the OR gate in the circuitry for the intermediate vertex 1606. In an alternative embodiment, the circuitry for the vertex 1606 includes a direct coupling (e.g. a wire) between the output of the circuitry for input-consuming edge 1 and the input terminal of the OR gate in the circuitry for the intermediate vertex 1606. The first section 1702 of the circuitry for the condition edge 4 then receives the logical high signal output by the circuitry for input-consuming edge 1 either via a separate coupling, or via a coupling branching off of the circuitry for the intermediate vertex 1606.

In any case, the first section 1702 incudes logic which, on receipt of the logical high signal from the circuitry for input-consuming edge 1, outputs a signal to the third section 1706 of the circuitry for the condition edge 4, said signal asserting that the present input token output by the input buffer is the first input token for the rule “Name” of the grammar. This is because, as defined in the grammar of ANTLR G4 SPECIFICATION 5, the rule “Name” begins after the input token”. On the clock tick on which the register in the circuitry for input-consuming edge 1 outputs a logical high, the input buffer will output the next token in the input data.

Upon receipt of the logical high signal from the first portion 1702, the third portion 1706 includes logic which stores the present input token (which in this case is “f” for the input data “, f, r, e, d,” required for a successful parse).

Upon the next clock tick, the new input token output by the buffer will be “r”, and thus the circuitry for input-consuming edge 1 will no longer output logical high, and thus the first section 1702 will no longer output a logical high to the third portion 1706. However, the circuitry for input-consuming edge 2 will now output a logical high signal to the circuitry for intermediate vertex 1608 because the previous input token “f” satisfied the input-consumption condition “==‘[a-z]’”. The third portion 1706 includes logic which, on receipt of the logical high signal from circuitry for intermediate vertex 1608, again stores the present input token (in this case “r”). This process will then repeat analogously for the next two input tokens, “e” and “d”, such that the third portion 1706 has each of the tokens “f”, “r”, “e”, and “d” stored.

The circuitry for input-consuming edge 2 is also coupled to the second portion 1704 of the circuitry for condition edge 4 (e.g. via the circuitry for intermediate vertex 1608 in the present embodiment), so that the logical high signal output by the circuitry for input-consuming edge 2 also propagates to the second portion 1704. The second portion 1704 of the circuitry for the condition edge 4 includes logic that checks if the current input token output by the buffer is ″. If the current input token output by the buffer is ″, and, if the second portion 1704 is receiving a logical high signal from the circuitry for input-consuming edge 2, the second portion 1704 outputs a signal to the third section 1706 of the circuitry for the condition edge 4, said signal asserting that the previous input token output by the input buffer is the last input token for the rule “Name” of the grammar. This is because, as defined in the grammar of ANTLR G4 SPECIFICATION 5, the rule “Name” ends before the input token”. In the present embodiment, on the clock tick after input token “d” is provided from the input buffer, the new token provided from the input buffer will be ″, and the second portion 1704 will be receiving a logical high signal from the circuitry for input-consuming edge 2. The second portion 1704 will therefore output the signal asserting that the previous input token d was the last input token from the rule “Name”.

The third portion 1706 includes logic that, upon receiving the logical high signal from the second portion 1704, coverts the input tokens stored by the third portion 1706 (i.e. “f”, “r”, “e”, and “d”) to the relevant attribute (as specified in the condition element), and stores this attribute value in memory, such as a register. In this case, the third portion stores the native string form, i.e. “fred”, as the text attribute of the input tokens identified as included in the “Name” rule. The third portion 1706 then compares the comparison value (i.e. “fred”) with the stored attribute. If the stored attribute matches the comparison value of the condition element, the third portion 1706 will output a logical high signal to the circuitry for input-consuming edge 5. In this way, the third portion 1706 selectively permits propagation of a logical high based on the condition element. A successful parse can only occur if the condition of the condition element is met, because otherwise the third portion 1706 would not output a logical high signal to allow parsing to continue. In the present embodiment, assuming the condition is met, once the third portion 1706 outputs a logical high signal to the circuitry for input-consuming edge 5, the circuitry for input-consuming edge 5 can (on the next clock tick) output a logical high signal to the circuitry for the end vertex 1604, because the present input token output by the input buffer is ″.

In the above-described embodiment of FIG. 17, the implemented circuitry for the condition edge 4 actually stores to memory each of the input tokens identified by the first and second portions 1702,1704 as corresponding to the rule “Name”. As an example, this may be achieved by providing multiple registers, each to store a single token in sequence, or may be achieved by providing a single memory location in a memory that is capable of storing a string that is appended to by each character, or may be achieved by providing a buffer to continuously store a given number of most-recently consumed input tokens, e.g. by way of a hardware ring buffer.

In some embodiments, it is not the values of the input tokens themselves that are stored for downstream circuitry to evaluate the function defined in the computer code of the condition element, but instead a value derived from the input tokens, such as the output of a mathematical function of an input token's value, or some property of the input token. Exactly what is stored will depend on the comparison to be performed by the circuitry to evaluate the function defined in the computer code of the condition element.

In some embodiments, the comparison of the input tokens (or the input token derivatives) based on the condition may be performed incrementally as each input token is consumed (e.g. at the point at when each input token is output by the input buffer, or at the point when the input buffer advances to the next input token). The partial evaluation result for each input token from this incremental comparison may be stored in memory for subsequent use when deriving the complete evaluation result for the function defined in the computer code of the condition element (i.e. once an input token has been asserted as the last input token for the relevant rule of the grammar).

The circuitry for the condition edge 4 is configured to identify the range of input tokens corresponding to the relevant rule of the grammar. As described in the embodiment above, this can be done by the implemented circuitry for the condition edge tracking when an input token is consumed by the input-consuming edge immediately prior to the relevant rule of the grammar (input-consuming edge 1 in the embodiment of FIGS. 16 and 17), and also when an input token is consumed by the input-consuming edge immediately following the relevant rule of the grammar (input-consuming edge 5 in the embodiment of FIGS. 16 and 17).

In the case of embedded networks, the first input token of the rule of the embedded network is identified by the set of calling edges that call that rule (e.g. as an embedded network). Similarly, the last input token is identified by the corresponding set of returning edges that return from that rule. It is noted that a rule of the grammar, such as “Name” in FIGS. 16 and 17, may be an inlined embedded network in some embodiments.

Once the circuitry for the condition edge 4 has identified a sequence of input tokens corresponding to the relevant rule of the grammar, the sequence of input tokens must be converted to the alternative representation for the relevant condition element, e.g. the attribute. For example, if the ‘int’ attribute is present in the condition element, a run of numeric text characters (from the sequence of input tokens) can be converted to an integer representation and placed in a register or other memory in the circuitry of the condition edge 4, to allow evaluation of the condition. In some embodiments, this could be achieved by streaming the sequence of input tokens (whether received from the input buffer, or stored by the circuitry for the condition edge 4 itself) into a string-to-integer conversion module with suitable start/end flags. Such a conversion module could be statically coded in some embodiments, as all string-to-integer conversions are the same (aside from bit depth limits which can be handled via generic parameters).

In some embodiments, generic steps for auto-coding may comprise one or more (e.g. all) of the following: 1) identifying, from relevant condition element, the rule attribute in use; 2) identifying the corresponding (statically-coded) conversion module and instantiating it; 3) hooking up the input stream (accompanied by start/end flags derived from the start/end edges of a rule or calling/returning edges for the rule); and 4) hooking up the conversion module output to the appropriate condition edge circuitry.

The skilled reader will recognise that many different numerical and non-numerical conversions are possible and the techniques of this disclosure are not limited to any specific examples recited in the present disclosure.

For condition elements that perform a check on an attribute for a particular rule of a grammar, the condition elements require the value of the attribute (or a value derived from the attribute) to be stored to allow comparison with the comparison value. The storage of this value is analogous to the storage of a value for the locally defined variable during the action elements of the previous embodiment. In this way, the condition elements of the present embodiment can be through of as including “implicit” actions to store the attribute value or value derived from the attribute, which are needed to evaluate the condition. Thus even though a grammar description might not contain an action element, a condition element may still imply an action to store a value for use in evaluating the function defined by the condition element.

In some embodiments, the grammar description includes an explicit action element, even if the action is implied by the condition element. For example, the grammar description may include an explicit action element (separate to the condition element) that performs the storage of the attribute value for the sequence of input tokens for a rule of the grammar, or storage of a value derived from the attribute value. The transition network would then include an action edge associated with this action element as well as the condition edge and the implemented circuitry for this action edge would perform the role of storage of the attribute value or value derived therefrom in memory. The implemented circuitry for the condition edge would then be located downstream of the implemented circuitry for the corresponding action edge, and would perform the role of evaluating the function defined in the computer code of the condition element based on value stored by the circuitry for the action edge. This might result in same or similar hardware to that generated based on a grammar description for the same grammar where the action is implied by the condition element and the grammar description does not include an explicit action element to perform the storage of a value needed for evaluation of the function defined in the computer code of the condition element.

In the embodiment described above, the condition element {$Name.text==‘fred’}? is an example of a static condition element. A static condition element has a comparison value that is fixed and predetermined by the grammar description, in this case “fred”. However, some embodiments use dynamic condition elements, where the condition element includes a dynamic comparison value. Such dynamic comparison values are not predetermined values defined by the grammar description, but are instead non-fixed values stored in memory. A dynamic comparison value might be, for example, an attribute for a sequence of input tokens corresponding to an earlier rule of the grammar. For example, if the grammar description included a first rule “Rule1” and a second rule “Rule2”, where “Rule 2” is downstream of “Rule 1” in the ATN of that grammar, a dynamic condition element could be {$Rule2.text==$Rule1.text}?. In this way, the text attribute of the sequence of input tokens corresponding to (i.e. parsed in accordance with) Rule2 must match the text attribute of a previous sequence of different input tokens in the input data which corresponded to Rule 1. The comparison value is set by the specific input tokens present in the input data (corresponding to Rule 1), rather than being predetermined in the grammar description.

Some embodiments include other types of condition elements for checking attributes of rules in the grammar description. For example, a condition element could check that the ‘int’ attribute for a sequence of input tokens corresponding to a rule satisfies some form of mathematical equation or inequality, such as a range. An example of a condition element which checks a trigonometric function of ‘int’ attribute will be discussed in more detail below.

In some embodiments, the transition network (e.g. ATN) may include condition elements that check attributes for a particular rule of the grammar as described in the present section of this disclosure, in combination with action and condition elements operating on locally defined variables, as described in the previous section of this disclosure. For such a transition network, the hardware description may include instructions for implementing circuitry as described in relation to both FIGS. 10 and 11, and FIG. 17.

The techniques described in the present section of this disclosure may additionally or alternatively be combined with the embedded network techniques discussed in relation to FIGS. 1 to 6.

### Downstream Application for Condition Elements

In previously described embodiments corresponding to FIGS. 7 to 17, it has been assumed that condition elements are able to be evaluated by the condition edge circuitry in a single clock cycle, and/or that the transition network has been optimised according to the methods described in relation to FIGS. 12 to 15 to avoid input pipeline stalls when evaluating the conditions.

In some embodiments, the computer code of a condition element defines an operation that requires more than clock cycle to be evaluated by the implemented circuitry for the relevant condition edge in the hardware description. For example, a condition element such as ‘{cos ($Number.int)>0.5}?’ may require multiple clock cycles to be evaluated by implemented circuitry for the condition edge. When implementing a transition network in hardware having such a condition element using the methods described above, the input pipeline would need to be stalled while this condition was evaluated.

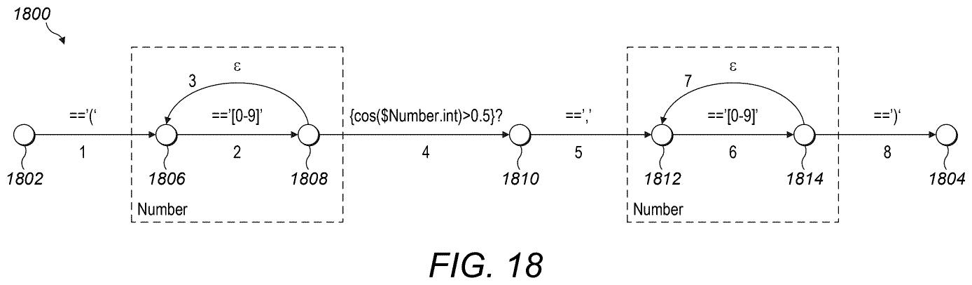

In order to prevent such pipeline stalls, techniques are described below where result of the function defined by the condition element is applied to the parsing outcome (i.e. propagation is selectively permitted) at a location further downstream in the digital electronic circuit, as will be discussed in relation to FIGS. 18 to 20. This allows additional clock cycles for the result of the function to be obtained without delaying stalling the pipeline.

A grammar description including a condition element of the type that checks an attribute for a rule of the grammar is shown below in ANTLR G4 SPECIFICATION 6:

ANTLR G4 SPECIFICATION 6

```
Top:
  ‘(‘ Number {cos($Number.int)>0.5}? ’,‘ Number ’)’
Number:
  ‘[0-9]’+
```

An ATN representing the grammar description of ANTLR G4 SPECIFICATION 6 is shown in FIG. 18. The ATN 1800 of FIG. 18 includes a start vertex 1802 and an end vertex 1804. The start vertex 1802 is the source vertex for an input-consuming edge 1 with the input-consumption condition “== ‘(’”. The input-consuming edge 1 has intermediate vertex 1806 as its destination vertex. Intermediate vertex 1806 is connected to an intermediate vertex 1808 by an input-consuming edge 2 with the input-consumption condition “==‘[0-9]”. The intermediate vertex 1808 is connected to intermediate vertex 1806 via an epsilon transition 3. The intermediate vertex 1808 is also connected to an intermediate vertex 1810 via a condition edge 4 associated with the condition element ‘{cos ($Number.int)>0.5}?’ from the grammar description. The intermediate vertex 1810 is the source vertex for an input-consuming edge 5 with the input-consumption condition “==‘,’”. The input-consuming edge 5 has intermediate vertex 1812 as its destination vertex. Intermediate vertex 1812 is connected to an intermediate vertex 1814 by an input-consuming edge 6 with the input-consumption condition “==‘[0-9]’”. The intermediate vertex 1814 is connected to intermediate vertex 1812 via an epsilon transition 7. The intermediate vertex 1814 is also connected the end vertex 1804 input-consuming edge 8 with the input-consumption condition “== ‘)’”. If this digital electronic circuit is used to parse input data, there will likely be pipeline stalls due to the long time needed to evaluate the condition of condition edge 4, i.e. the implementation of the trigonometric function.

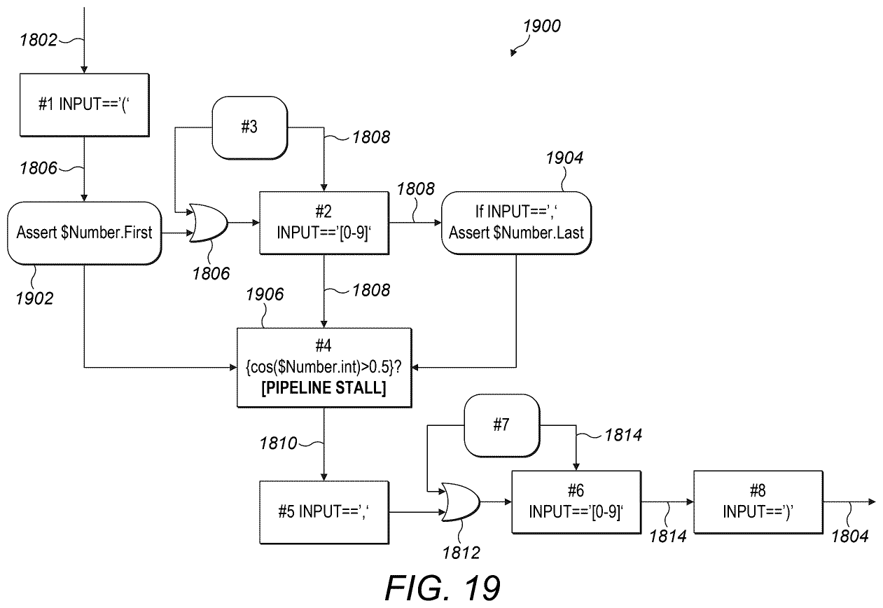

FIG. 19 shows a schematic logical diagram of a digital electronic circuit 1900 created according to a hardware description generated based on ATN 1800 using the methods described in relation to FIGS. 16 and 17. The digital electronic circuit 1900 of FIG. 19, including the first, second and third portions 1902, 1904, 1906 of the circuitry for the condition edge 4, is analogous to the circuitry described in FIG. 17. In the digital electronic circuit 1900 of FIG. 19, it is necessary to stall the input pipeline in digital electronic circuit 1900 for multiple clock cycles while the cosine function of the condition element is evaluated by the third portion 1906 of the circuitry for condition edge 4.

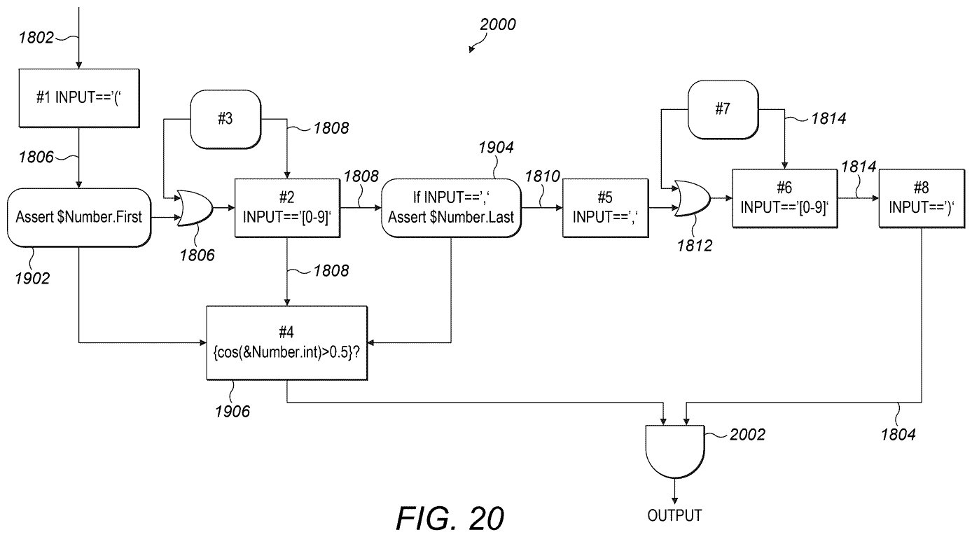

FIG. 20 shows a schematic logical diagram of an alternative digital electronic circuit 2000 created according to a hardware description generated based on ATN 1800 wherein the result of the evaluation of the condition element is delayed in application, i.e. it is applied further downstream. The digital electronic circuit 2000 differs from that of FIG. 19 in that the third portion 1906 of the circuitry for condition edge 4 is not coupled to the circuitry for input-consuming edge 5. Instead the second portion 1904 of the circuitry for condition edge 4 is coupled to the circuitry for input-consuming edge 5 (i.e. the implemented circuitry for intermediate vertex 1810 provides a coupling between the second portion 1904 of the circuitry for condition edge 4 and the circuitry for input-consuming edge 5). When the second portion 1904 outputs a logical high signal to the third portion 1906, asserting that the previous input token output by the input buffer is the last input token for the rule “Number” of the grammar, the second portion 1904 will also output a logical high signal to the circuitry for input-consuming edge 5, allowing parsing by the digital electronic circuit to continue regardless of the evaluation of the function defined by the condition element associated with condition edge 4, i.e. the evaluation of the cosine function.

The logic in the third portion 1906 of the circuitry for condition edge 4 can then evaluate the condition element, i.e. check that the cosine of the ‘int’ attribute of the input tokens corresponding to the rule “Number” is greater than the comparison value 0.5. This evaluation of the function defined in the condition element can take place over a number of clock cycles of the digital electronic circuit, and will therefore occur in parallel to continued propagation of the logical high signal through the implemented circuitry of edges 5, 6, 7 and 8 of the digital electronic circuit 2000.

Once the third portion 1906 has evaluated the condition, the third portion 1906 outputs a logical high signal if the condition is met, and this logical high signal can be applied downstream of the third portion 1906 in the digital electronic circuit 2000 to take into account the condition result. For example, the logical high signal can be combined with the logical high signal propagating through the digital electronic circuit 2000 as a result of the logical high signal output by the second portion 1904 to circuitry for input-consuming edge 5, in a manner such that a logical high signal will only be output by the digital electronic circuit 2000 if both the remaining parsing of the input data is successful and the condition is met.

In the present embodiment, the implemented circuitry for condition edge 4 further includes logic 2002, an AND gate in this instance, to perform the application of the condition element result. A first terminal of the AND gate of logic 2002 is coupled to the third portion 1906 to receive any logical high signal output by the third portion 1906. A second terminal of the AND gate is coupled to the end vertex 1804 to receive any logical high signal output by the circuitry for input-consuming edge 8. In this way, the output of the AND gate 2002 will only be logical high if both the circuitry for input-consuming edge 8 outputs a logical high (indicating a successful parse of the input data against the grammar ignoring the condition element), and if the third portion 1906 outputs a logical high (indicating that the condition of the condition element is met). In this way, the AND gate of logic 2002 will only output a logical high if the input data conforms to the grammar of ANTLR G4 SPECIFICATION 6.

By applying the evaluated result of a condition element further downstream in the digital electronic circuit, a pipeline stall is prevented because the digital electronic circuit can proceed on the assumption that the condition is satisfied without stalling (i.e. by the second portion 1904 outputting a logical high to the circuitry for input-consuming edge 5). Then, further downstream in the digital electronic circuit the results of the condition evaluation are combined via a logical AND with the output of a later input-consuming edge circuitry. Therefore, even if a logical high signal is output by the later input-consuming edge circuitry, the final output of the digital electronic circuit as a whole will only be logical high if the condition has also been met. In some embodiments, the results of the condition evaluation are combined with the result of the remaining parse that proceeded under the assumption that the condition was satisfied at or proximate to the final output of the digital electronic circuit.

As this example demonstrates, the circuitry for a condition edge does not generally need to evaluate the function of the condition element and prevent propagation of the logical high signal through the digital electronic circuit at the same location within the digital electronic circuit. Instead the condition edge circuitry can prevent propagation of the logical high signal at any location in the digital electronic circuit downstream of the circuitry for storing of the appropriate value in the memory on which the evaluation of the condition's function depends, provided that it is applied far enough downstream to allow sufficient clock cycles for the condition's function to be evaluated. Some embodiments can implement circuitry for one or more condition edges with delayed (downstream) application of a outcome of the function of the associated condition element even when the outcome can be obtained within a single clock cycle.

While the examples presented here show delayed/downstream application of the result of the function of a condition edge for a Rules-Attributes-based condition element, in which the values derived from input tokens are checked, the same delayed/downstream application may also be used for condition elements using a local-variable-based condition element, such as one checking a count as described above.

Relative Positioning of Circuitry for Action and Condition Elements within a Digital Electronic Circuit

The following represents a list of optional principles or rules for the placement or positioning of circuitry for action and condition elements in a digital electronic circuit and in the hardware description for the circuit in accordance with the techniques described herein. Embodiments in accordance with the techniques of this disclosure are not required to apply these principles or rules but may optionally follow one, some or all of them.

Before proceeding it is helpful to define, for the purposes of these optional principles or rules, what is meant by an action and what is meant by a condition. For the purposes of these rules, an action is any side-effect (i.e. manipulation of supplementary state/memory) with the specific aim of enabling a condition to be evaluated. This includes implied actions as discussed above. A condition is a logical assertion (based on action side-effects) that determines if a corresponding edge is viable/enabled for parse progression at any given point (t) in the parse.

Condition processing can be sub-divided into three steps: 1) Qualification, which comprises determining if the condition edge at time (t) is part of the unambiguous successful parse; 2) Evaluation, which comprises determining the Boolean result of the condition at time (t); and 3) Application, which comprises influencing the parse outcome based on the evaluation result. Application can be direct (causing the parser to fall out of state by inhibiting an edge, i.e. preventing propagation of a logical high signal by that edge, or preventing propagation further downstream as done in digital electronic circuit 2000 of FIG. 20), or application indirect (tracking failures to meet conditions separately and combining them with the primary result of the parser, i.e. where parsing proceeds on the assumption that the condition is satisfied).

There are two main strategies for exploiting conditions. A first type is the closing down of alternatives (Type 1), where conditions are used to make the grammar unambiguous where it otherwise wouldn't be (essentially providing a “parsing hint”). An example might be to check a counter to decide when to carry on looping over input tokens within a rule and when to leave. Another example might be to check a counter to decide when it is acceptable for the parser to leave a rule defined in the grammar description, as illustrated by the condition elements in FIG. 8. A second type is the checking of input tokens (Type 2), where conditions add extra constraints to unambiguous grammars. An example might be to check that an attribute of an input token or sequence of input tokens (e.g. a field) in the input data has a specific value, e.g. is a number in the range 1 to 3, has a natural string value ‘fred’ (such as the condition elements in FIG. 16 or 18). It is noted that an unambiguous grammar is not always deterministic at the location of the condition edge within a transition network. A degree of look-ahead may be needed to resolve whether the condition edge is part of a successful parse or not.

The processing implications are different for each scenario. For Type 1 (closing down alternatives), qualification is not a relevant concept in this scenario. Application is direct because the parser may break unless the false path is shut down. Application might be immediate at the point where the circuitry corresponding to the condition edge is encountered, although application could be deferred via ANDing into appropriate edges downstream of the condition edge, such as in the manner shown in the digital electronic circuit 2000 of FIG. 20. For Type 2 (the checking of input tokens), qualification will depend on the grammar. It may take place before, at or after the circuitry for the condition edge is encountered but at a deterministic point. Application can be direct or indirect, but will require qualification when indirect. Evaluation must complete prior to application.

When presented with a grammar, it may not be immediately obvious which of these strategies applies to each condition (i.e. each predicate using ANTLR terminology). There are various analytical techniques that will be familiar to the skilled reader for determining if a grammar is unambiguous for all possible inputs.

The earliest an action can start is when, for the first time: 1) given the current parsing state, the corresponding action edge (or circuitry for implied action as part of a condition edge) is inevitably traversed as part of all successful parses; and 2) dependencies on parser input are satisfied. The first property can be checked for any point on the graph via straightforward transition network graph analysis. An action must complete before any subsequent action manipulating the same supplementary state/memory starts and any condition depending on the outcome of the action begins evaluation.

Condition evaluation can begin when all action dependencies are satisfied. A condition must evaluate before any action dependencies are invalidated by subsequent actions and before the condition is applied. When indirect application is used, a condition cannot be applied before the condition is qualified. A condition must be applied before (in the case of Type 1) the parser breaks by encountering a condition beyond its design limits, (for example: an action on false path A invalidates some supplementary state on true path B, or a sub-network/rule X is entered on path A while rule X is active on path B). The condition must also be applied before the end of the parse. A condition qualifies when the condition is Type 1 or when, given the current parsing state, the condition edge is known to be part of all successful parses. Merely encountering the edge is not sufficient to determine that the condition edge is known to be part of all successful parses because the condition edge could be at a nondeterministic point in the transition network graph.

Whether the condition edge is to be part of all successful parses can be checked via graph analysis on the transition network. This may comprise the following: 1) for any point (P) upstream of the condition edge in the graph, see if the condition edge is downstream for all possible paths and check if the condition edge target node is a deterministic point; if yes then the condition edge is qualified at point P, i.e. it is known that the condition edge is inevitably part of the parse; and 2) for any point (P) downstream of the condition edge target node, i.e. on a path containing the condition edge, check to see if point P is deterministic; if yes then the condition edge is qualified at point P.

Simpler and frequently encountered scenarios include the following scenarios. In a first scenario, the condition edge's source node is the source for no other edges. This means the condition is qualified as soon as encountering the condition edge becomes inevitable during the parse. In a second scenario, the condition edge is at a fork with N alternatives and the grammar is LL(1) at the source of the condition edge. This means that the condition is qualified (or fails to qualify) as soon as the next input is evaluated.

An application of these rules or principles may comprise some or all of the following steps:
1) identifying conditions (i.e. predicates) and associated actions;
2) identifying the positional constraints for each action and the three processing steps of the condition;
3) determining if direct or indirect application is to be used;
4) choosing points in the transition network to trigger each action such that the relevant positional constraints are satisfied;
5) either choosing a point in the transition network to trigger condition evaluation (e.g. storing the result in a register for downstream application) or evaluating the condition continuously in combinational logic;
6) storing the result for use later in a register if evaluation happens (is completed) before application and it is necessary for the result to persist over clock cycles;
7) for direct application: i) choosing the edges to which the condition will be applied, allowing for time (clock cycles) for the evaluation to complete, and ii) combining (AND-ing) the condition result into the chosen condition application edges;
8) for indirect application: i) identifying suitable points that indicate the condition is qualified, ii) tracking condition evaluations and corresponding qualification events, iii) accumulating qualified condition results in a condition failure register (i.e. setting the register when any condition is positively qualified and fails evaluation), and iv) at the end of the parse, combining the final value of the condition failure register with the result of the primary parse.

These steps represent one way in which circuitry for action edges and condition edges and portions thereof can be positioned within a digital electronic circuit but the skilled person may recognise that it is not necessary to follow all of these steps in all situations. Some embodiments do not include all of these steps. The skilled person will recognise that other approaches may achieve effective implementations without these steps, particularly for many common scenarios and for data formats defined by many categories of grammar.

### CONCLUSION

In general, each of the methods and techniques described in relation to FIGS. 7 to 20 may be combined with the embedded network techniques discussed in relation to FIGS. 1 to 6.

Some of the examples presented herein use the terminology ‘ATN’, although the techniques of this disclosure are generally applicable to transition networks representative of a grammar description that includes i) one or more condition elements, or ii) one or more action elements and one or more condition elements.

The preceding discussion describes the generation for a hardware description for configuring a digital electronic circuit to parse input data comprising a sequence of input tokens against a grammar that defines a data format. In such examples, it assumed that the input data has previously been lexed into the sequence of separate input tokens before the digital electronic circuit processes them from the input buffer. The skilled reader should note that some implementations may additionally include a lexing stage within the hardware description to lex any unseparated input data into the sequence of tokens and supply the input tokens to the input buffer for parsing. A resulting digital electronic circuit may include such a lexing stage within the same hardware (e.g. same FPGA device) as the circuitry for parsing the input data in the form of lexed input tokens.

The skilled reader will appreciate that the various illustrative logical blocks, configurations, modules, circuits, and algorithm steps described in connection with the embodiments disclosed herein may be implemented as electronic hardware, computer system software, or combinations of both. To clearly illustrate this interchangeability of hardware and software, various illustrative components, blocks, configurations, modules, circuits, and steps have been described above generally in terms of their functionality. Whether such functionality is implemented as hardware or software depends upon the particular application and design constraints imposed on the overall system. The skilled reader may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in software executed by a processor, or in a combination of the two. If implemented in software, the functions may be stored on or transmitted over, as one or more instructions or code, a computer system-readable medium and executed by a hardware-based processing unit. Computer-readable media may include computer-system-readable storage media, which corresponds to a tangible medium such as data storage media, or communication media including any medium that facilitates transfer of a computer system program from one place to another, e.g., according to a communication protocol. In this manner, computer system-readable media generally may correspond to tangible computer system-readable storage media which is non-transitory or alternatively to a communication medium such as a signal or carrier wave. Data storage media may be any available media that can be accessed by one or more computer systems or one or more processors to retrieve instructions, code and/or data structures for implementation of the techniques described in this disclosure.

The present disclosure makes reference to signals that are ‘logical high’. These signals might not necessarily have a higher voltage value than a ‘logical low’, but instead are intended to refer to a signal representative of ‘one’ or ‘true’, as compared with ‘zero’ or ‘false’.

The previous description of the disclosed embodiments is provided to enable any person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

1. A computer-implemented method of generating a hardware description for configuring a digital electronic circuit to parse input data comprising a sequence of input tokens against a grammar that defines a data format, wherein the grammar is codified in a grammar description that includes one or more condition elements, or includes one or more action elements and one or more condition elements, wherein the one or more condition elements comprise computer code that define functions that provide Boolean output based on values stored in memory, wherein the method comprises:
providing a digitally stored graph representing a transition network based on the rules of the grammar, the transition network including one or more condition edges that are each associated with a condition element; and
generating the hardware description in a hardware description language or as a netlist based on the transition network,
wherein the hardware description includes implemented circuitry for a condition edge, the implemented circuitry for the condition edge configured to evaluate the function defined in the computer code of the associated condition element based on a stored value in memory,
wherein, the implemented circuitry for the condition edge is configured to, based on the output of the function, selectively permit propagation of a logical high through implemented circuitry at a location downstream of the storing of the value in the memory.

2. The method of claim 1, further comprising configuring a digital electronic circuit based on the hardware description.

3. A digital electronic circuit for parsing input data comprising a sequence of input tokens against a grammar that defines a data format, wherein the grammar is codified in a grammar description that includes one or more condition elements, or includes one or more action elements and one or more condition elements, wherein the one or more condition elements comprise computer code that define functions that provide Boolean output based on values stored in memory, wherein the digital electronic circuit is configured according to the method of claim 2.

4. A computer system for generating a hardware description for configuring a digital electronic circuit to parse input data comprising a sequence of input tokens against a grammar that defines a data format, wherein the grammar is codified in a grammar description that includes one or more condition elements, or includes one or more action elements and one or more condition elements, wherein the one or more condition elements comprise computer code that define functions that provide Boolean output based on values stored in memory, wherein the computing system comprises a memory having instructions stored thereon and a processor, the processor configured to execute the instructions stored in the memory of the computing system to:
provide a digitally stored graph representing a transition network based on the rules of the grammar, the transition network including one or more condition edges that are each associated with a condition element; and
generate the hardware description in a hardware description language or as a netlist based on the transition network,
wherein the hardware description includes implemented circuitry for a condition edge, the implemented circuitry for the condition edge configured to evaluate the function defined in the computer code of the associated condition element based on a stored value in memory of the digital electronic circuit,
wherein, the implemented circuitry for the condition edge is configured to, based on the output of the function, selectively permit propagation of a logical high through implemented circuitry at a location downstream of the storing of the value in the memory of the digital electronic circuit.

5. A computer-implemented method of generating a hardware description for configuring a digital electronic circuit to parse input data comprising a sequence of input tokens against a grammar that defines a data format, wherein the grammar is codified in a grammar description that includes one or more condition elements, wherein a condition element comprises computer code that defines a function that provides a Boolean output based on at least one value stored in memory, wherein the method comprises:
providing a digitally stored graph representing a transition network based on the rules of the grammar; and
generating the hardware description in a hardware description language or as a netlist based on the transition network,
wherein the transition network comprises a plurality of vertices and a plurality of directed edges connected between vertices, each directed edge connected between a respective source vertex and destination vertex, the plurality of directed edges of the transition network comprising a plurality of input-consuming edges and a plurality of non-input-consuming edges, the plurality of non-input-consuming edges including one or more action edges and one or more condition edges,
wherein each input-consuming edge represents a transition between its source vertex and its destination vertex conditional on a current input token of the input data matching an input-consumption condition associated with the input-consuming edge, wherein parsing of the input data advances to a next input token of the input data with the transition,
wherein each non-input-consuming edge represents a transition between its source vertex and its destination vertex without the parsing of the input data advancing to a next input token of the input data with the transition,
wherein each condition edge of the one or more condition edges is associated with a condition element of the grammar description, wherein at least one condition edge of the one or more condition edges is associated with a condition element that comprises computer code that defines a function that provides a Boolean output based on a comparison between a stored value derived from one or more input tokens and a comparison value,
wherein generating the hardware description comprises implementing an input buffer in the hardware description to store a sequence of input tokens of the input data, the input buffer configured to provide an input token of the sequence of input tokens as output from the input buffer, wherein the input buffer is further configured to sequentially advance through the sequence of input tokens by, on a clock tick, providing a next input token as output from the input buffer,
wherein generating the hardware description further comprises implementing a memory in the hardware description, the memory configured to store a value and provide the stored value as output from the memory,
wherein generating the hardware description further comprises implementing circuitry in the hardware description for the edges and vertices of the transition network,
wherein the implemented circuitry for each vertex is electrically connected to the implemented circuitry for each edge that is connected to the vertex in the transition network, the implemented circuitry for each vertex configured to output a logical high to circuitry for all outgoing directed edges of that vertex if circuitry for an incoming directed edge of that vertex provides a logical high,
wherein the implemented circuitry for each input-consuming edge comprises a register with associated logic configured to compare an input token provided as output from the input buffer with the input-consumption condition associated with that input-consuming edge, the register with associated logic configured to, if the implemented circuitry for the source vertex of the input-consuming edge provides a logical high and the input token provided as output from the input buffer satisfies the input-consumption condition of the input-consuming edge, provide a logical high to circuitry for the destination vertex of the input-consuming edge on a next clock tick, the input buffer advancing to a next input token and providing the next input token as output from the input buffer on said next clock tick,
wherein the implemented circuitry for each non-input-consuming edge comprises a coupling between circuitry for the source vertex of the non-input-consuming edge and circuitry for the destination vertex of the non-input-consuming edge,
wherein the implemented circuitry for the at least one condition edge of the one or more condition edges is configured to store a first value derived from one or more input tokens in the memory and, at a location within the digital electronic circuit downstream of the storing of the first value in the memory, evaluate the function defined in the computer code of the associated condition element based on a comparison between the stored value derived from one or more input tokens in the memory and the comparison value, and, based on the output of the function, selectively permit propagation of a logical high through implemented circuitry at a location downstream of the storing of the first value in the memory.

6. The method of claim 5, wherein the comparison value for the condition edge of the one or more condition edges is: i) defined in the grammar description, or ii) stored in memory and derived from one or more different input tokens.

7. The method of claim 5,
wherein the plurality of non-input-consuming edges of the transition network comprises a plurality of condition edges including first and second condition edges,
wherein the implemented circuitry for each of the first and second condition edges is configured to store a respective first or second value derived from one or more input tokens in the memory and, at a location within the digital electronic circuit downstream of the storing of the respective first or second value in the memory, evaluate the function defined in the computer code of the associated condition element based on a comparison between the stored respective first or second value and a respective first or second comparison value, and, based on the output of the function, selectively permit propagation of a logical high through implemented circuitry at a location downstream of the storing of the respective first or second value in the memory.

8. The method of claim 7, wherein the implemented circuitry for each of the first and second condition edges stores the respective first or second value at a same memory location, wherein the implemented circuitry for the second condition edge that stores the second value in memory is positioned within the digital electronic circuit downstream of the implemented circuitry for the first condition edge that reads the first value from the same memory location.

9. The method of claim 5, further comprising configuring a digital electronic circuit based on the hardware description.

10. A digital electronic circuit for parsing input data comprising a sequence of input tokens against a grammar that defines a data format, wherein the grammar is codified in a grammar description that includes one or more condition elements, wherein a condition element comprises computer code that defines a function that provides a Boolean output based on at least one value stored in memory, wherein the digital electronic circuit is configured according to the method of claim 9.

11. A computer system for generating a hardware description for configuring a digital electronic circuit to parse input data comprising a sequence of input tokens against a grammar that defines a data format, wherein the grammar is codified in a grammar description that includes one or more condition elements, wherein a condition element comprises computer code that defines a function that provides a Boolean output based on at least one value stored in memory, wherein the computing system comprises a memory having instructions stored thereon and a processor, the processor configured to execute the instructions stored in the memory of the computing system to:
provide a digitally stored graph representing a transition network based on the rules of the grammar; and
generate the hardware description in a hardware description language or as a netlist based on the transition network,
wherein the transition network comprises a plurality of vertices and a plurality of directed edges connected between vertices, each directed edge connected between a respective source vertex and destination vertex, the plurality of directed edges of the transition network comprising a plurality of input-consuming edges and a plurality of non-input-consuming edges, the plurality of non-input-consuming edges including one or more action edges and one or more condition edges,
wherein each input-consuming edge represents a transition between its source vertex and its destination vertex conditional on a current input token of the input data matching an input-consumption condition associated with the input-consuming edge, wherein parsing of the input data advances to a next input token of the input data with the transition,
wherein each non-input-consuming edge represents a transition between its source vertex and its destination vertex without the parsing of the input data advancing to a next input token of the input data with the transition,
wherein each condition edge of the one or more condition edges is associated with a condition element of the grammar description, wherein at least one condition edge of the one or more condition edges is associated with a condition element that comprises computer code that defines a function that provides a Boolean output based on a comparison between a stored value derived from one or more input tokens and a comparison value,
wherein generating the hardware description comprises implementing an input buffer in the hardware description to store a sequence of input tokens of the input data, the input buffer configured to provide an input token of the sequence of input tokens as output from the input buffer, wherein the input buffer is further configured to sequentially advance through the sequence of input tokens by, on a clock tick, providing a next input token as output from the input buffer,
wherein generating the hardware description further comprises implementing a memory of the digital electronic circuit in the hardware description, the memory of the digital electronic circuit configured to store a value and provide the stored value as output from the memory of the digital electronic circuit,
wherein generating the hardware description further comprises implementing circuitry in the hardware description for the edges and vertices of the transition network,
wherein the implemented circuitry for each vertex is electrically connected to the implemented circuitry for each edge that is connected to the vertex in the transition network, the implemented circuitry for each vertex configured to output a logical high to circuitry for all outgoing directed edges of that vertex if circuitry for an incoming directed edge of that vertex provides a logical high,
wherein the implemented circuitry for each input-consuming edge comprises a register with associated logic configured to compare an input token provided as output from the input buffer with the input-consumption condition associated with that input-consuming edge, the register with associated logic configured to, if the implemented circuitry for the source vertex of the input-consuming edge provides a logical high and the input token provided as output from the input buffer satisfies the input-consumption condition of the input-consuming edge, provide a logical high to circuitry for the destination vertex of the input-consuming edge on a next clock tick, the input buffer advancing to a next input token and providing the next input token as output from the input buffer on said next clock tick,
wherein the implemented circuitry for each non-input-consuming edge comprises a coupling between circuitry for the source vertex of the non-input-consuming edge and circuitry for the destination vertex of the non-input-consuming edge,
wherein the implemented circuitry for the at least one condition edge of the one or more condition edges is configured to store a first value derived from one or more input tokens in the memory of the digital electronic circuit and, at a location within the digital electronic circuit downstream of the storing of the first value in the memory of the digital electronic circuit, evaluate the function defined in the computer code of the associated condition element based on a comparison between the stored value derived from one or more input tokens in the memory of the digital electronic circuit and the comparison value, and, based on the output of the function, selectively permit propagation of a logical high through implemented circuitry at a location downstream of the storing of the first value in the memory of the digital electronic circuit.

12. A computer-implemented method of generating a hardware description for configuring a digital electronic circuit to parse input data comprising a sequence of input tokens against a grammar that defines a data format, wherein the grammar is codified in a grammar description that includes one or more action elements and one or more condition elements, wherein an action element comprises computer code for an operation that comprises storing a value in memory, wherein a condition element comprises computer code that defines a function that provides a Boolean output based on at least one value stored in memory, wherein the method comprises:
providing a digitally stored graph representing a transition network based on the rules of the grammar; and
generating the hardware description in a hardware description language or as a netlist based on the transition network,
wherein the transition network comprises a plurality of vertices and a plurality of directed edges connected between vertices, each directed edge connected between a respective source vertex and destination vertex, the plurality of directed edges of the transition network comprising a plurality of input-consuming edges and a plurality of non-input-consuming edges, the plurality of non-input-consuming edges including one or more action edges and one or more condition edges,
wherein each input-consuming edge represents a transition between its source vertex and its destination vertex conditional on a current input token of the input data matching an input-consumption condition associated with the input-consuming edge, wherein parsing of the input data advances to a next input token of the input data with the transition,
wherein each non-input-consuming edge represents a transition between its source vertex and its destination vertex without the parsing of the input data advancing to a next input token of the input data with the transition,
wherein each action edge of the one or more action edges is associated with an action element of the grammar description,
wherein each condition edge of the one or more condition edges is associated with a condition element of the grammar description,
wherein generating the hardware description comprises implementing an input buffer in the hardware description to store a sequence of input tokens of the input data, the input buffer configured to provide an input token of the sequence of input tokens as output from the input buffer, wherein the input buffer is further configured to sequentially advance through the sequence of input tokens by, on a clock tick, providing a next input token as output from the input buffer,
wherein generating the hardware description further comprises implementing a memory in the hardware description, the memory configured to store a value and provide the stored value as output from the memory,
wherein generating the hardware description further comprises implementing circuitry in the hardware description for the edges and vertices of the transition network,
wherein the implemented circuitry for each vertex is electrically connected to the implemented circuitry for each edge that is connected to the vertex in the transition network, the implemented circuitry for each vertex configured to output a logical high to circuitry for all outgoing directed edges of that vertex if circuitry for an incoming directed edge of that vertex provides a logical high,
wherein the implemented circuitry for each input-consuming edge comprises a register with associated logic configured to compare an input token provided as output from the input buffer with the input-consumption condition associated with that input-consuming edge, the register with associated logic configured to, if the implemented circuitry for the source vertex of the input-consuming edge provides a logical high and the input token provided as output from the input buffer satisfies the input-consumption condition of the input-consuming edge, provide a logical high to circuitry for the destination vertex of the input-consuming edge on a next clock tick, the input buffer advancing to a next input token and providing the next input token as output from the input buffer on said next clock tick,
wherein the implemented circuitry for each non-input-consuming edge comprises a coupling between circuitry for the source vertex of the non-input-consuming edge and circuitry for the destination vertex of the non-input-consuming edge,
wherein the implemented circuitry for an action edge of the one or more action edges comprises circuitry configured to perform an operation in accordance with the computer code of the associated action element, wherein the operation stores a first value in the memory,
wherein the implemented circuitry for a condition edge of the one or more condition edges is configured to, at a location within the digital electronic circuit downstream of the implemented circuitry for the action edge that stores the first value in the memory, evaluate the function defined in the computer code of the associated condition element based on the first value, and, based on the output of the function, selectively permit propagation of a logical high through implemented circuitry at a location downstream of the implemented circuitry for the action edge that stores the first value in the memory.

13. The method of claim 12,
wherein at least one action edge of the one or more action edges is associated with an action element that comprises computer code for storing a value derived from one or more input tokens in memory,
wherein the implemented circuitry for that action edge is configured to, in accordance with the computer code of the associated action element, store the value derived from one or more input tokens in memory,
wherein at least one condition edge of the one or more condition edges is associated with a condition element that comprises computer code that defines a function that provides a Boolean output based on a comparison between the stored value derived from one or more input tokens and a comparison value,
wherein the implemented circuitry for that condition edge is configured to: downstream of the implemented circuitry for the action edge that stores the value derived from one or more input tokens in the memory, evaluate the function defined in the computer code of the associated condition element based on the stored value derived from one or more input tokens in the memory and the comparison value.

14. The method of claim 12,
wherein at least one condition edge of the one or more condition edges is associated with a condition element that comprises computer code that defines a function that provides a Boolean output based on a comparison between a stored value derived from one or more input tokens and a comparison value,
wherein the implemented circuitry for that condition edge is configured to store a second value derived from one or more input tokens in the memory and, at a location within the digital electronic circuit downstream of the storing of the second value in the memory, evaluate the function defined in the computer code of the condition element based on a comparison between the stored value derived from one or more input tokens in the memory and the comparison value, and, based on the output of the function, selectively permit propagation of a logical high through implemented circuitry at a location downstream of the storing of the second value in the memory.

15. The method of claim 13, wherein the comparison value is: i) defined in the grammar description, or ii) stored in memory and derived from one or more different input tokens.

16. The method of claim 12, wherein at least one action edge of the one or more action edges is associated with an action element that comprises computer code for initializing a variable, wherein the implemented circuitry for that action edge is configured to, in accordance with the computer code of the associated action element, store a predetermined value in memory.

17. The method of claim 12, wherein at least one action edge of the one or more action edges is associated with an action element that comprises computer code for adjusting a variable, wherein the implemented circuitry for that action edge is configured to, in accordance with the computer code of the associated action element: i) read a value stored in memory, ii) adjust the value, and iii) store the adjusted value in memory.

18. The method of claim 17, wherein adjusting a value comprises adding a number to the value.

19. The method of claim 17, wherein at least one condition edge is associated with a condition element that comprises computer code for enforcing a counting rule of the grammar, wherein the counting rule applies to input tokens within a portion of the input data and requires that the number of input tokens that satisfy a particular input-consumption condition within that portion of the input data is either a predetermined number or within a predetermined range, wherein the implemented circuitry for that condition edge is configured to, downstream of the implemented circuitry for the action edge that stores the adjusted value in the memory, make a comparison based on the value stored in memory in accordance with the counting rule and, based on the output of the comparison, selectively permit propagation of a logical high through implemented circuitry at a location downstream of the implemented circuitry for the action edge that stores the adjusted value in the memory.

20. The method of claim 19, wherein the grammar is recursive and the counting rule of the grammar requires, at each of a plurality of levels of recursion including a first level and a second level, that the number of input tokens at that level of recursion that satisfy the particular input-consumption condition is either a predetermined number or within a predetermined range, wherein generating the hardware description comprises:
implementing one or more stacks including a first stack in the hardware description;
implementing circuitry for, in association with a transition from the first to the second level of recursion, pushing a value stored in memory in accordance with the counting rule for the first level of recursion to the first stack; and
implementing circuitry for, in association with a transition from the second to the first level of recursion, popping the value from the first stack to memory for use in accordance with the counting rule for the first level of recursion.

21. The method of claim 12,
wherein the plurality of non-input-consuming edges of the transition network comprises a plurality of action edges including first and second action edges and a plurality of condition edges including first and second condition edges,
wherein the implemented circuitry for each of the first and second action edges comprises circuitry configured to perform an operation in accordance with computer code of an associated action element, wherein the operation stores a respective value in the memory,
wherein the implemented circuitry for each of the first and second condition edges is configured to, downstream of the implemented circuitry for the respective first or second action edge, evaluate the function defined in the computer code of the associated condition element based on the value stored by the implemented circuitry for the respective first or second action edge, and, based on the output of the function, selectively permit propagation of a logical high through implemented circuitry at a location downstream of the implemented circuitry for the respective first or second action edge.

22. The method of claim 21, wherein the implemented circuitry for each of the first and second action edges stores respective values at a same memory location, wherein the implemented circuitry for the second action edge that performs the operation of storing a value is positioned within the digital electronic circuit downstream of the implemented circuitry for the first condition edge that reads a value from the same memory location.

23. The method of claim 12, wherein implementing a memory in the hardware description comprises implementing one or more registers in the hardware description, wherein the implemented circuitry for at least one condition edge of the one or more condition edges is configured to evaluate the function defined in the computer code of the condition element associated with that condition edge based on a value stored in one or more registers.

24. The method of claim 12, wherein the implemented circuitry for at least one condition edge of the one or more condition edges is configured to evaluate the function defined in the computer code of the condition element associated with that condition edge over more than one clock cycle of the digital electronic circuit.

25. The method of claim 12, wherein:
providing a digitally stored graph representing a transition network based on the rules of the grammar comprises providing a digitally stored graph representing a recursive transition network (RTN), based on the rules of the grammar other than any action elements or condition elements of the rules of the grammar,
any edges corresponding to action elements or condition elements of the grammar are represented in the RTN as epsilon transitions, and
generating the hardware description comprises implementing circuitry for the action edges and condition edges based on the computer code of the associated action element or condition element.

26. The method of claim 12, wherein
providing a digitally stored graph representing a transition network based on the rules of the grammar comprises providing a digitally stored graph representing an augmented transition network (ATN), based on the rules of the grammar including any action elements or condition elements of the rules of the grammar, and
any edges corresponding to action elements or condition elements of the grammar are represented in the ATN as non-input-consuming edges that include the computer code of the associated action element or condition element.

27. The method of claim 12, wherein at least one vertex of the transition network has a plurality of incoming directed edges and the implemented circuitry for the vertex comprises a logical OR gate, wherein the implemented circuitry for each of the plurality of incoming directed edges of the vertex is electrically connected as an input to the logical OR gate.

28. The method of claim 12, wherein generating the hardware description comprises implementing a lexer in the hardware description, wherein the implemented lexer is configured to lex input data into a sequence of input tokens to be provided to the input buffer.

29. The method of claim 12, wherein the grammar description defines a data format that comprises: i) a JSON schema, or ii) an XML Schema Definition (XSD), or iii) an ASN.1 schema.

30. The method of claim 12, wherein the grammar is a context-free grammar that additionally includes rules defined by actions and conditions.

31. The method of claim 12, wherein the grammar is an LL(1) grammar.

32. The method of claim 12, wherein the hardware description for configuring the digital electronic circuit is generated in Verilog or VHDL.

33. The method of claim 12, further comprising configuring a digital electronic circuit based on the hardware description.

34. A digital electronic circuit for parsing input data comprising a sequence of input tokens against a grammar that defines a data format, wherein the grammar is codified in a grammar description that includes one or more action elements and one or more condition elements, wherein an action element comprises computer code for an operation that comprises storing a value in memory, wherein a condition element comprises computer code that defines a function that provides a Boolean output based on at least one value stored in memory, wherein the digital electronic circuit is configured according to the method of claim 33.

35. The digital electronic circuit of claim 34, wherein the digital electronic circuit is an application-specific integrated circuit (ASIC) or a field-programmable gate array (FPGA).

36. A computer system for generating a hardware description for configuring a digital electronic circuit to parse input data comprising a sequence of input tokens against a grammar that defines a data format, wherein the grammar is codified in a grammar description that includes one or more action elements and one or more condition elements, wherein an action element comprises computer code for an operation that comprises storing a value in memory, wherein a condition element comprises computer code that defines a function that provides a Boolean output based on at least one value stored in memory, wherein the computing system comprises a memory having instructions stored thereon and a processor, the processor configured to execute the instructions stored in the memory of the computing system to:
provide a digitally stored graph representing a transition network based on the rules of the grammar; and
generate the hardware description in a hardware description language or as a netlist based on the transition network,
wherein the transition network comprises a plurality of vertices and a plurality of directed edges connected between vertices, each directed edge connected between a respective source vertex and destination vertex, the plurality of directed edges of the transition network comprising a plurality of input-consuming edges and a plurality of non-input-consuming edges, the plurality of non-input-consuming edges including one or more action edges and one or more condition edges,
wherein each input-consuming edge represents a transition between its source vertex and its destination vertex conditional on a current input token of the input data matching an input-consumption condition associated with the input-consuming edge, wherein parsing of the input data advances to a next input token of the input data with the transition,
wherein each non-input-consuming edge represents a transition between its source vertex and its destination vertex without the parsing of the input data advancing to a next input token of the input data with the transition,
wherein each action edge of the one or more action edges is associated with an action element of the grammar description,
wherein each condition edge of the one or more condition edges is associated with a condition element of the grammar description,
wherein generating the hardware description comprises implementing an input buffer in the hardware description to store a sequence of input tokens of the input data, the input buffer configured to provide an input token of the sequence of input tokens as output from the input buffer, wherein the input buffer is further configured to sequentially advance through the sequence of input tokens by, on a clock tick, providing a next input token as output from the input buffer,
wherein generating the hardware description further comprises implementing a memory of the digital electronic circuit in the hardware description, the memory of the digital electronic circuit configured to store a value and provide the stored value as output from the memory of the digital electronic circuit,
wherein generating the hardware description further comprises implementing circuitry in the hardware description for the edges and vertices of the transition network,
wherein the implemented circuitry for each vertex is electrically connected to the implemented circuitry for each edge that is connected to the vertex in the transition network, the implemented circuitry for each vertex configured to output a logical high to circuitry for all outgoing directed edges of that vertex if circuitry for an incoming directed edge of that vertex provides a logical high,
wherein the implemented circuitry for each input-consuming edge comprises a register with associated logic configured to compare an input token provided as output from the input buffer with the input-consumption condition associated with that input-consuming edge, the register with associated logic configured to, if the implemented circuitry for the source vertex of the input-consuming edge provides a logical high and the input token provided as output from the input buffer satisfies the input-consumption condition of the input-consuming edge, provide a logical high to circuitry for the destination vertex of the input-consuming edge on a next clock tick, the input buffer advancing to a next input token and providing the next input token as output from the input buffer on said next clock tick,
wherein the implemented circuitry for each non-input-consuming edge comprises a coupling between circuitry for the source vertex of the non-input-consuming edge and circuitry for the destination vertex of the non-input-consuming edge,
wherein the implemented circuitry for an action edge of the one or more action edges comprises circuitry configured to perform an operation in accordance with the computer code of the associated action element, wherein the operation stores a first value in the memory of the digital electronic circuit,
wherein the implemented circuitry for a condition edge of the one or more condition edges is configured to, at a location within the digital electronic circuit downstream of the implemented circuitry for the action edge that stores the first value in the memory of the digital electronic circuit, evaluate the function defined in the computer code of the associated condition element based on the first value, and, based on the output of the function, selectively permit propagation of a logical high through implemented circuitry at a location downstream of the implemented circuitry for the action edge that stores the first value in the memory of the digital electronic circuit.
